(19) United States
(12) Patent Application Publication
(10) Pub. No.: US 2026/0040890 A1
(43) Pub. Date: Feb. 5, 2026

(54) SUBSTRATE PROCESSING EQUIPMENT

(71) Applicant: Samsung Electronics Co., Ltd., Suwon-si (KR)

(72) Inventors: Byoung Min YUN, Suwon-si (KR); Juhyun KIM, Suwon-si (KR); Hyunseok SIN, Suwon-si (KR); Wonhee LEE, Suwon-si (KR); Kwanhui JO, Suwon-si (KR); Younsok CHOI, Suwon-si (KR)

(21) Appl. No.: 19/036,267

(22) Filed: Jan. 24, 2025

(30) Foreign Application Priority Data
Aug. 2, 2024 (KR) 10-2024-0103351

(51) Int. Cl. H01L 21/687; H01J 37/32; H01L 21/68

(52) U.S. Cl. CPC H01L 21/68735; H01J 37/32642; H01J 37/32715; H01L 21/68; H01J 2237/2007; H01J 2237/24578; H01J 2237/334

(57) ABSTRACT

Provided is substrate processing equipment including a substrate supporter including a chuck including a receiving surface that is flat on which a substrate is placed, a ring structure that is placed along an edge of the substrate supporter at a predetermined distance, and a substrate type sensor that is placed on the receiving surface, and the substrate type sensor includes a body part including a first surface facing the receiving surface and a second surface that is an opposite surface of the first surface, wherein a groove is formed on at least a portion of an edge of the second surface, a shooting apparatus that is placed at the groove and configured to shoot at least one surface of the groove and at least a portion of one side of the ring structure, and a control apparatus configured to control the shooting apparatus and calculate length of the ring structure.

### CROSS-REFERENCE TO RELATED APPLICATION(S)

This application claims the benefit of priority under 35 U.S.C. § 119 to Korean Patent Application No. 10-2024-0103351, filed on Aug. 2, 2024, in the Korean Intellectual Property Office, the entire disclosure of which is incorporated herein by reference.

### BACKGROUND

### 1. Field of the Invention

Example embodiments relate to substrate processing equipment.

### 2. Description of the Related Art

In order to manufacture semiconductor devices or liquid crystal displays, various processes such as photolithography, etching, ashing, ion implantation, thin film deposition and cleaning are performed on a substrate (for example, a wafer). It is advantageous in terms of the process to transfer or return the substrate into the chamber and perform transforming and returning automatically in order to perform the various processes.

Meanwhile, in order to fix the substrate during the etching process and to uniformly distribute the etching material (for example, radical or plasma) on the surface of the substrate, an edge ring (or a focus ring) may be placed along the edge of the substrate. The edge ring can be etched together with the substrate during the etching process, and the shape of the edge ring can gradually change through repeated etching processes, thereby changing the etching characteristics of the edge ring with respect to the substrate. Therefore, the edge ring needs to be replaced at the appropriate time, and in order to identify the appropriate time, it is important to check the etched amount of the edge ring.

### SUMMARY

An aspect provides substrate processing equipment by which the etched amount of a ring structure such as an edge ring may be effectively measured, and a substrate may be placed in a correct position on a chuck to be aligned.

The technical tasks to be achieved by the present example embodiments are not limited to the technical tasks described above, and other technical tasks may be inferred from the following example embodiments by those skilled in the art.

According to an aspect, there is provided substrate processing equipment including a substrate supporter including a chuck including a receiving surface that is flat and on which a substrate is placed, a ring structure that is placed along an edge of the substrate supporter at a predetermined distance in a first direction parallel to the receiving surface, and a substrate type sensor that is placed on the receiving surface, wherein the substrate type sensor includes a body part including a first surface facing the receiving surface based on a second direction perpendicular to the receiving surface and a second surface that is an opposite surface of the first surface, wherein a groove is formed on at least a portion of an edge of the second surface, a shooting apparatus that is placed at the groove and configured to shoot at least one surface of the groove and at least a portion of one side of the ring structure, and a control apparatus configured to control the shooting apparatus and calculate length of the ring structure in the second direction.

According to another aspect, there is provided substrate processing equipment including a substrate supporter including a chuck including a receiving surface that is flat and on which a substrate is placed, a ring structure that is placed along an edge of the substrate supporter at a predetermined distance in a first direction parallel to the receiving surface, and a substrate type sensor that is placed on the receiving surface, wherein the substrate type sensor includes a body part including a first surface facing the receiving surface based on a second direction perpendicular to the receiving surface and a second surface that is an opposite surface of the first surface, wherein a groove is formed on at least a portion of an edge of the second surface, a surface part shooting apparatus that is placed at the body part and does not overlap the groove when viewed from the second direction, a control apparatus configured to control the shooting apparatus and calculate a length of the ring structure in the second direction, and a light member that does not overlap the groove when viewed in the second direction and has a structure protruding from the second surface.

According to another aspect, there is provided substrate processing equipment including a chamber that is at least a portion of a processing space where a substrate is processed, a source supplying apparatus configured to generate at least one of plasma and radical, a shower head configured to distribute the at least one of the plasma and the radical to the processing space, a substrate supporter including a chuck including a receiving surface that is flat and on which a substrate is placed, a ring structure that is placed along an edge of the substrate supporter at a predetermined distance in a first direction parallel to the receiving surface, and a substrate type sensor that is placed on the receiving surface, wherein the substrate type sensor includes a body part including a first surface facing the receiving surface based on a second direction perpendicular to the receiving surface and a second surface that is an opposite surface of the first surface, wherein a groove is formed on at least a portion of an edge of the second surface, a shooting apparatus that is placed at the groove and configured to shoot at least one surface of the groove and at least a portion of one side of the ring structure, a control apparatus configured to control the shooting apparatus and calculate a length of the ring structure in the second direction, a first region that is formed between the substrate type sensor and the ring structure, and formed in one side based on the first direction, and a second region that is formed between the substrate type sensor and the ring structure, and formed on another side based on the first direction, and wherein the control apparatus is configured to derive an etched amount of the ring structure by calculating a length difference of the ring structure in the second direction with respect to before and after etching the substrate, or calculate a difference between a first separation distance that is a separation distance of the first region when the separation distance of the first region and a separation distance of the second region are identical and a second separation distance that is the separation distance of the first region when the separation distance of the first region and the separation distance of the second region are different.

Additional aspects of example embodiments will be set forth in part in the description which follows and, in part, will be apparent from the description, or may be learned by practice of the disclosure.

According to example embodiments, it is possible to provide substrate processing equipment by which the etched amount of a ring structure such as an edge ring is effectively measured, and alignment is performed in order to ensure that a substrate is positioned correctly on a chuck.

The effect of the example embodiments is not limited to the above-described effects, and other effects not described would be clearly understood by those skilled in the art from the description of the claims.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a cross-sectional view illustrating at least a portion of substrate processing equipment according to an example embodiment;

FIG. 2 is a plan view illustrating at least a portion of a substrate type sensor and at least a portion of a ring structure according to an example embodiment;

FIG. 3 is an enlarged view of a portion A1 of FIG. 1, and is a cross-sectional view illustrating at least a portion of substrate processing equipment according to an example embodiment;

FIG. 4 is an enlarged view of a portion A2 of FIG. 2, and is a plan view illustrating at least a portion of a substrate type sensor and at least a portion of a ring structure according to an example embodiment;

FIG. 5 is an enlarged view of the portion A2 of FIG. 2, and is a plan view illustrating at least a portion of a substrate type sensor and at least a portion of a ring structure according to an example embodiment;

FIG. 6 is a perspective view illustrating at least a portion of a substrate type sensor according to an example embodiment;

FIG. 7 illustrates a photographing result taken by a substrate type sensor according to an example embodiment;

FIG. 8 is an enlarged view of the portion A2 of FIG. 2, and is a plan view illustrating at least a portion of a substrate type sensor and at least a portion of a ring structure according to an example embodiment;

FIG. 9 is a perspective view illustrating at least a portion of a substrate type sensor according to an example embodiment;

FIG. 10 illustrates a photographing result taken by a substrate type sensor according to an example embodiment;

FIG. 11 is an enlarged view of the portion A1 of FIG. 1, and is a cross-sectional view illustrating at least a portion of substrate processing equipment according to an example embodiment;

FIG. 12 illustrates a photographing result using a substrate type sensor according to an example embodiment;

FIG. 13 is a plan view illustrating at least a portion of a substrate type sensor and at least a portion of a ring structure according to an example embodiment;

FIG. 14 is an enlarged view of the portion A1 of FIG. 1, and is a cross-sectional view illustrating at least a portion of substrate processing equipment according to an example embodiment;

FIG. 15 illustrates a photographing result taken by a substrate type sensor according to an example embodiment;

FIG. 16 is an enlarged view of the portion A1 of FIG. 1, and is a cross-sectional view illustrating at least a portion of substrate processing equipment according to an example embodiment;

FIG. 17 illustrates a photographing result using a substrate type sensor according to an example embodiment;

FIG. 18 is a plan view illustrating at least a portion of a substrate type sensor and at least a portion of a ring structure according to an example embodiment;

FIG. 19 is an enlarged view of the portion A1 of FIG. 1, and is a cross-sectional view illustrating at least a portion of substrate processing equipment according to an example embodiment;

FIG. 20 illustrates a photographing result taken by a substrate type sensor according to an example embodiment;

FIG. 21 is an enlarged view of the portion A1 of FIG. 1, and is a cross-sectional view illustrating at least a portion of substrate processing equipment according to an example embodiment;

FIG. 22 illustrates a photographing result taken by a substrate type sensor according to an example embodiment;

FIG. 23 is an enlarged view of the portion A2 of FIG. 2, and is a plan view illustrating at least a portion of a substrate type sensor and at least a portion of a ring structure according to an example embodiment;

FIG. 24 is a perspective view illustrating at least a portion of a substrate type sensor according to an example embodiment;

FIG. 25 illustrates a photographing result taken by a substrate type sensor according to an example embodiment;

FIG. 26 is a perspective view illustrating at least a portion of a substrate type sensor according to an example embodiment;

FIG. 27 illustrates a photographing result taken by a substrate type sensor according to an example embodiment;

FIG. 28 is an enlarged view of the portion A1 of FIG. 1, and is a cross-sectional view illustrating at least a portion of substrate processing equipment according to an example embodiment;

FIG. 29 is an enlarged view of the portion A1 of FIG. 1, and is a cross-sectional view illustrating at least a portion of substrate processing equipment according to an example embodiment;

FIG. 30 illustrates a photographing result taken by a substrate type sensor according to an example embodiment;

FIG. 31 is an enlarged view of the portion A1 of FIG. 1, and is a cross-sectional view illustrating at least a portion of substrate processing equipment according to an example embodiment;

FIG. 32 illustrates a photographing result using a substrate type sensor according to an example embodiment;

FIG. 33 is an enlarged view of the portion A1 of FIG. 1, and is a cross-sectional view illustrating at least a portion of substrate processing equipment according to an example embodiment;

FIG. 34 illustrates a photographing result using a substrate type sensor according to an example embodiment;

FIG. 35 is an enlarged view of the portion A1 of FIG. 1, and is a cross-sectional view illustrating at least a portion of substrate processing equipment according to an example embodiment;

FIG. 36 is an enlarged view of the portion A2 of FIG. 2, and is a plan view illustrating at least a portion of a substrate type sensor and at least a portion of a ring structure according to an example embodiment;

FIG. 37 is a perspective view illustrating at least a portion of a substrate type sensor according to an example embodiment;

FIG. 38 illustrates a photographing result taken by a substrate type sensor according to an example embodiment;

FIG. 39 is a perspective view illustrating at least a portion of a substrate type sensor according to an example embodiment;

FIG. 40 illustrates a photographing result taken by a substrate type sensor according to an example embodiment;

FIG. 41 is an enlarged view of portion A3 of FIG. 13, and is a plan view illustrating at least a portion of a substrate type sensor and at least a portion of a ring structure according to an example embodiment;

FIG. 42 is an enlarged view of portion A4 of FIG. 18, and is a plan view illustrating at least a portion of a substrate type sensor and at least a portion of a ring structure according to an example embodiment;

FIG. 43 is an enlarged view of the portion A2 of FIG. 2, and is a plan view illustrating at least a portion of a substrate type sensor and at least a portion of a ring structure according to an example embodiment;

FIG. 44 is a perspective view illustrating a shooting apparatus according to an example embodiment;

FIG. 45 is an enlarged view of the portion A1 of FIG. 1, and is a cross-sectional view illustrating at least a portion of substrate processing equipment according to an example embodiment;

FIG. 46 is an enlarged view of the portion A2 of FIG. 2, and is a plan view illustrating at least a portion of a substrate type sensor and at least a portion of a ring structure according to an example embodiment;

FIG. 47 illustrates a photographing result taken by a substrate type sensor according to an example embodiment;

FIG. 48 is an enlarged view of the portion A2 of FIG. 2, and is a plan view illustrating at least a portion of a substrate type sensor and at least a portion of a ring structure according to an example embodiment; and

FIG. 49 is a plan view illustrating at least a portion of a substrate processing system according to an example embodiment.

### DETAILED DESCRIPTION

Prior to the detailed description of the present disclosure, terms or words used in the specification and claims may not be construed as limited to their common or dictionary meanings. Further, the terms or words should be interpreted with meaning and concept consistent with the technical idea of the present disclosure based on the principle that the inventor may appropriately define the concept of terms in order to explain his or her invention in the best way. The example embodiments described in this specification and the configurations shown in the drawings are only example embodiments of the present disclosure, and do not necessarily represent the entire technical idea of the present disclosure. Accordingly, at the time of filing the present disclosure, there may be various equivalents and modifications that can replace them.

The same reference numeral or sign shown in each drawing attached to the specification may represent parts or components that perform substantially the same function. For convenience of description and understanding, different embodiments may be described using the same reference numerals or symbols. In other words, even if a component or an element having the same reference numeral is shown in multiple drawings, the multiple drawings may not all represent one example embodiment.

In the present disclosure, when an element is described as being “directly on” or “in contact with” another element, the element may be understood as being in direct contact with or connected to the another element, and it may be understood that there is no other element between the two.

Further, in the present disclosure, when an element is described as being “on an upper portion” or “on an upper surface” of another element, it may be understood as existing above the vertical direction, for example, as being above the +D2 direction in the drawing, and the two elements may be in direct contact or connected, but it may also be understood that another element exists between the two. The same is applied even when an element is described as being “above” another element in the present disclosure.

Further, in the present disclosure, when an element is described as being “on a lower portion” or “on a lower surface” of another element, it may be understood as existing below based on the vertical direction, for example, being further below based on the −D2 direction in the drawing, and the two elements may be in direct contact or connected, but it may also be understood that another element exists between the two. The same is applied even when an element is described as being “below” another element.

Other similar expressions describing the positional relationship between elements can also be interpreted similarly as above.

In the following description, singular expressions include plural expressions unless the context clearly dictates otherwise. It will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. The terms “have,” “may have,” “include,” and “may include” as used herein indicate the presence of corresponding features (for example, elements such as numerical values, functions, operations, or parts), and do not preclude the presence of additional features.

Further, in the following description, expressions such as upper side, upper surface, lower side, lower surface, side, a front side and a back side are expressed based on the direction shown in the drawing. If the direction of the object changes, it may be expressed differently.

Further, in the specification and claims, terms including ordinal numbers such as “first,” “second,” etc. may be used to distinguish between components or elements. These ordinal numbers are used to distinguish identical or similar components from each other, and the meaning of the terms should not be interpreted limitedly due to the use of such ordinal numbers. For example, components or elements combined with these ordinal numbers should not be interpreted as having a limited order of use or arrangement based on the number. If necessary, each ordinal number may be used interchangeably.

The drawings illustrated in the present disclosure are example embodiments, and the ratio of the width, the length and the height (or the thickness) of each element is for detailed descriptions for the example embodiments, and thus the ratio may differ from reality. Further, in the coordinate system illustrated in the drawings, each axis may be perpendicular to each other, and the direction the arrow points may be the + direction, and the direction opposite to the direction indicated by the arrow (rotated by 180 degrees) may be the −direction.

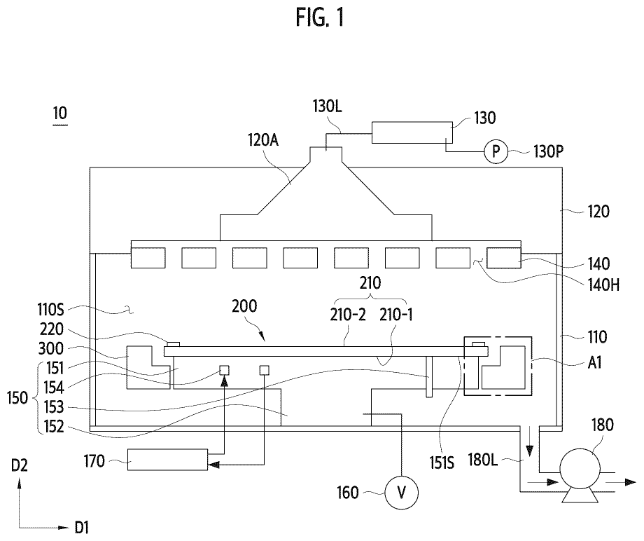

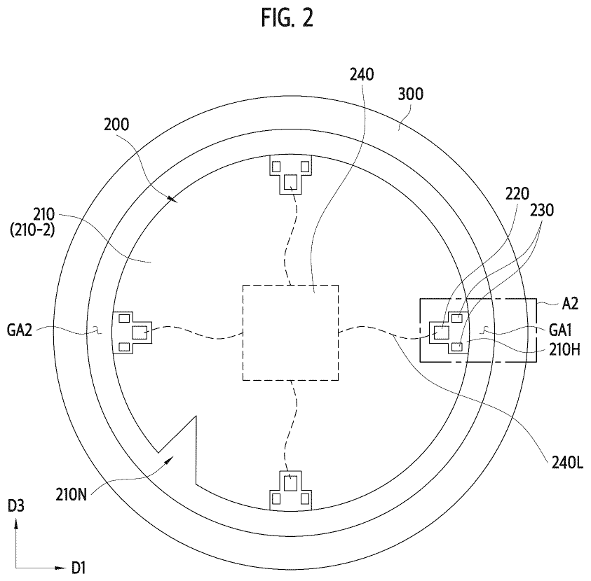

FIG. 1 is a cross-sectional view illustrating at least a portion of substrate processing equipment 10 according to an example embodiment. FIG. 2 is a plan view illustrating at least a portion of a substrate type sensor 200 and at least a portion of a ring structure 300 according to an example embodiment.

According to an example embodiment, the substrate processing equipment 10 may include a chamber 110, a lid 120, a source supplying apparatus 130, an energy supplying apparatus 130P, an adaptor 120A, and a shower head 140.

In an example embodiment, the substrate processing equipment 10 may be chamber-type equipment for processing a substrate using at least one of plasma and radical. For example, the substrate processing equipment 10 may be equipment that performs an etching process using at least one of plasma and radical, but the substrate processing equipment 10 is not limited thereto. The substrate processing equipment 10 may be equipment that performs the lithography process, the ashing process, the ion implantation process, the thin film deposition process, and/or the cleaning process.

In an example embodiment, the substrate may indicate the substrate itself or a laminated structure including the substrate and a predetermined layer or film formed on a surface of the substrate. Further, the surface of the substrate may indicate the exposed surface of the substrate itself or the exposed surface of a predetermined layer or film formed on the substrate. For example, the substrate may be a wafer or may include a wafer and at least one film of material on the wafer. Here, the material film may be at least one of an insulating film and a conductive film formed on a wafer through various methods such as deposition, coating, and plating. For example, the insulation film may include an oxide film, a nitride film, or an oxide-nitride film, and the conductive film may include a metal film or a polysilicon film. Meanwhile, the material film may be a single film or a multi-film formed on a wafer. Further, the material film may be formed on a wafer with a predetermined pattern.

In an example embodiment, the substrate processing equipment 10 may include the chamber 110 defining at least a portion of a processing space 110S in which the substrate is processed. Specifically, the processing space 110S may be defined by the chamber 110, the lid 120, and the shower head 140. The processing space 110S may be sealed from the outside.

In an example embodiment, the outer structure of the chamber 110 may have the shape of a cylinder, an elliptical column, or a polygonal column, but the outer structure of the chamber 110 is not limited thereto. Further, the chamber 110 may contain a metal material, and the electrical ground state may be maintained to block noise from outside.

In an example embodiment, a liner (not illustrated) may be placed inside the chamber 110. The liner may protect the chamber 110 and cover the metal structure inside the chamber 110 to minimize metal contamination caused by arcing inside. In an example embodiment, the liner may include a metal material such as aluminum, a ceramic material and so on. For example, the liner may be a plasma-resistant yttrium oxide (Y₂O₃) film, but is not limited thereto.

In an example embodiment, the substrate processing equipment 10 may include a discharge apparatus 180 for discharging byproducts within the chamber 110 to the outside after the process. The discharge apparatus 180 may be a pump, and byproducts inside the chamber 110 may be discharged to the outside after the process through a discharge line 180L fluidly connected to inside of the chamber 110. Meanwhile, the discharge apparatus 180 may also perform the function of regulating the pressure inside the chamber 110.

In an example embodiment, the shower head 140 may be placed inside the substrate processing equipment 10. The shower head 140 may include a plurality of holes 140H to allow fluid to move. At least one of the plasma and radical supplied from outside the chamber 110 may be evenly supplied or distributed to the processing space 110S through the plurality of holes 140H.

In an example embodiment, the shower head 140 may contain metal material, and a reflective layer (not illustrated) including a material that reflects light may be placed on the surface facing the processing space 110S (the −D2 direction in FIG. 1).

In an example embodiment, the source supplying apparatus 130 may be located outside the chamber 110. The source supplying apparatus 130 may generate at least one of plasma and radical through the energy supplying apparatus 130P. Further, the source supplying apparatus 130 may supply at least one of the generated plasma and radical to the processing space 110S through a source supplying line 130L. At least one of the generated plasma and radical may be supplied to the processing space 110S via the adaptor 120A and the shower head 140. Meanwhile, the energy supplying apparatus 130P may generate at least one of plasma and radicals by applying energy to a gas. In an example embodiment, the energy supplied to the gas by the energy supplying apparatus 130P may be radio frequency (RF) power (RF power) in the form of electromagnetic waves having a predetermined frequency and intensity. Further, the energy supplied by the energy supplying apparatus 130P may be supplied to the gas in the form of a continuous wave with an on-off cycle in the form of electromagnetic waves or in the form of pulses. An electric field may be generated by the energy supplying apparatus 130P, and a process gas supplied by the source supplying apparatus 130 into the processing space 110S may be excited to a plasma state. In example embodiments, the energy supplying apparatus 130P may include a magnetron and waveguide. In an example embodiment, at least one of the generated plasma and radical may be used in the lithography process, the ashing process, the ion implantation process, the thin film deposition process, or the cleaning process.

In an example embodiment, the adaptor 120A may be positioned between the source supplying apparatus 130 and the shower head 140. The adaptor 120A may include a passage for at least one of plasma and radical supplied from the source supplying apparatus 130. At least one of the plasma and radical generated by the source supplying apparatus 130 may be supplied to the shower head 140 through the adaptor 120A. The adaptor 120A may have a structure in which the area gradually decreases as the adaptor 120A moves away from the processing space 110S. In an example embodiment, the adaptor 120A may have a structure in which an area of the part connected to the source supplying line 130L is the smallest and an area facing the shower head 140 is the largest.

In an example embodiment, the lid 120 may be placed on the chamber 110. The lid 120 may enclose at least part of the adaptor 120A. The lid 120 may cover part of the shower head 140. Specifically, the lid 120 may cover any part except the part where the holes 140H are formed. The lid 120 may contain a metal material such as aluminum, but is not limited thereto.

In an example embodiment, the lid 120 may be maintained in an electrically grounded state to block noise applied from the outside. Further, a liner (not illustrated) may be placed on the inside of the lid 120. The descriptions of the liner placed in the chamber 110 may be referenced for the liner on the inside of the lid 120 to the extent that the descriptions are not contradictory.

In an example embodiment, the substrate processing equipment 10 may include a substrate supporter 150 positioned within the chamber 110. In an example embodiment, the substrate supporter 150 may include a chuck 151 having a flat receiving surface 151S on which a substrate is seated. Meanwhile, the substrate type sensor 200, which will be described later, may be mounted on the receiving surface 151S.

In an example embodiment, before the process is performed, after the substrate type sensor 200 described later is first installed on the receiving surface 151S, at least a portion of one side of the ring structure 300 described below may be photographed. Then, after the substrate type sensor 200 is taken out for process execution, the substrate may be taken in, after performing a process on the substrate (including the repeated process of taking the substrate out after performing the process and taking the substrate in before performing the process to perform an additional process), after taking the substrate out, by mounting the substrate type sensor 200, at least a portion of the one side of the ring structure 300 may be re-photographed. Through this, the substrate processing equipment 10 may quantitatively calculate the etched amount of the ring structure 300 by comparing the shooting result before the process and the shooting result after the process. More detailed descriptions about this are provided later.

Further, in an example embodiment, before the process is performed, after the substrate type sensor 200, which will be described later, is first mounted on the receiving surface 151S, at least a portion of the one side of the ring structure 300, which will be described later, may be photographed, by calculating whether the substrate type sensor 200 is positioned correctly or in an off-center position on the chuck 151, the substrate processing equipment 10 may perform alignment by placing the substrate in the correct position on the chuck 151 when the process is performed. More detailed descriptions about this are provided later.

In an example embodiment, the chuck 151 may hold a substrate or the substrate type sensor 200 mounted on the receiving surface 151S in position using electro-static force. The chuck 151 may include electrodes therein for chucking or de-chucking the substrate or the substrate type sensor 200. In an example embodiment, power wiring that is connected to the electrodes placed in the chuck 151 and transmits power from the outside may be placed within a chuck supporting board 152, which will be described later.

In an example embodiment, the chuck 151 may be configured to hold the substrate or the substrate type sensor 200 mounted on the receiving surface 151S in position through vacuum in addition to the electro-static force. Further, the chuck 151 may mechanically secure the substrate or the substrate type sensor 200 mounted on the receiving surface 151S.

In an example embodiment, the substrate supporter 150 may include the chuck supporting board 152 that supports the chuck 151. The chuck supporting board 152 may be formed of a metal such as aluminum or a ceramic insulator such as alumina (Al₂O₃).

In an example embodiment, the substrate supporter 150 may include a heating member 154 positioned within the chuck supporting board 152. Meanwhile, the substrate processing equipment 10 may include a heating apparatus 170 that transfers thermal energy to the heating member 154. The heating apparatus 170 may be located outside of the chamber 110. The heating apparatus 170 may transfer thermal energy to the heating member 154, the heating member 154 may transfer heat energy back to the chuck 151, and the chuck 151, which received thermal energy, may heat the substrate or the substrate type sensor 200 mounted on the receiving surface 151S by transferring the thermal energy thereto.

In an example embodiment, the substrate supporter 150 may include a lift pin 153 arranged to lift the substrate or the substrate type sensor 200 mounted on the receiving surface 151S. The lift pin 153 may be placed in a hole formed in the substrate supporter 150, and there may be a plurality of lift pins 153, and the plurality of lift pins 153 may be positioned in an arrangement appropriate for supporting and raising or lowering the substrate or the substrate type sensor 200 mounted on the receiving surface 151S.

In an example embodiment, the lift pin 153 may be pin-up from the substrate supporter 150 when the substrate or the substrate type sensor 200 is taken in or taken out of the substrate processing equipment 10. For example, when the lift pins 153 are in a pin-up position, upper ends of the lift pins 153 may be above a top surface of the chuck supporting board 152. Further, while the substrate is being processed in the chamber 110 or while the substrate type sensor 200 is photographing the ring structure 300, the lift pin 153 may be pin-down to allow the substrate or the substrate type sensor 200 to contact the receiving surface 151S. For example, when the lift pins 153 are in a pin-down position, upper ends of the lift pins 153 may extend be equal to or below the top surface of the chuck supporting board 152.

In an example embodiment, the substrate processing equipment 10 may include a bias supplying apparatus 160 that applies a bias voltage to the substrate supporter 150. The bias supplying apparatus 160 may apply RF power to the substrate supporter 150. The bias supplying apparatus 160 may apply low frequency RF power of less than about 200 kHz to the substrate supporter 150 while the process is being performed.

In an example embodiment, the substrate processing equipment 10 may include the ring structure 300 arranged along the edge of the substrate supporter 150 at a predetermined distance with respect to the first direction D1 parallel to the surface of the receiving surface 151S. For example, the ring structure 300 may be an edge ring (or a focus ring) that allows plasma or radicals to be supplied intensively to the substrate.

In the present disclosure, the first direction D1 (in FIG. 1) may indicate a single direction parallel to the surface of the receiving surface 151S. Further, the second direction D2 (in FIG. 1) to be described later may indicate a single direction perpendicular to the surface of the receiving surface 151S. Further, the third direction D3 (in FIG. 2) to be described later may indicate a single direction that is parallel to the surface of the receiving surface 151S, but perpendicular to the first direction D1 and the second direction D2.

In an example embodiment, the substrate processing equipment 10 may include the substrate type sensor 200 disposed on the receiving surface 151S. In an example embodiment, the substrate type sensor 200 includes a first surface 210-1 facing the receiving surface 151S along the second direction D2, a second surface 210-2 that is the opposite side of the first surface 210-1, and a body part 210 having a groove 210H formed in at least a portion of an edge of the second surface 210-2. The groove 210H may be formed on the second surface 210-2 through laser processing and so on without penetrating the body part 210 in the second direction D2.

In an example embodiment, the body part 210 may be equal in size to the substrate. Through this, the etched amount of the ring structure 300 may be quantitatively calculated, and further, the alignment may be performed in order for the substrate to be placed in the correct position on the chuck 151. In an example embodiment, the substrate type sensor 200 may be first taken in and mounted on the receiving surface 151S before the substrate is mounted on the receiving surface 151S. In an example embodiment, when the treatment process for the substrate is completed, the substrate is taken out and the substrate type sensor 200 may be taken in and mounted on the receiving surface 151S.

In an example embodiment, the body part 210 may include a notch 210N. The notch 210N may be positioned to align the substrate type sensor 200 on the substrate supporter 150. In an example embodiment, the notch 210N may be positioned at an edge of the body part 210, and may have a predetermined depth (length along the second direction) in a direction from the edge of the body part 210 toward the center. Further, in an example embodiment, the notch 210N may have a shape in which the circumference gradually decreases from the edge of the body part 210 toward the center.

In an example embodiment, the substrate type sensor 200 may include a shooting apparatus 220 disposed in the groove 210H. The shooting apparatus 220 is configured to shoot at least a portion of one side of the groove 210H and at least a portion of one side of the ring structure 300. In some embodiments, the substrate type sensor 200 may include a plurality of shooting apparatuses 220 disposed in the groove 210H to be positioned equidistant from one another. For example, in the embodiment illustrated in FIG. 2, the substrate type sensor 200 includes four shooting apparatuses 220 disposed in the groove 210H and positioned approximately 90 degrees apart from one another.

In an example embodiment, the substrate type sensor 200 may include a control apparatus 240 configured to control the shooting apparatus 220 and calculate the length along the second direction D2 of the ring structure 300. The control apparatus 240 may be configured to read the shooting results taken by the shooting apparatus 220 and calculate the length along the second direction D2 of the ring structure 300 based thereon. In some embodiments, the control apparatus 240 may include a circuit configured to perform the processes described herein. The control apparatus 240 may include dedicated circuitry or may include, for example, a central processing unit (CPU) chip, a graphic processing unit (GPU) chip, an application processor (AP) chip, an application specific integrated circuit (ASIC), or other processing chips.

In an example embodiment, the control apparatus 240 may be positioned in the central portion of the body part 210. Further, the control apparatus 240 may be connected to the shooting apparatus 220 via a connection line 240L for transmitting and receiving data. Each of the control apparatus 240 and the connection line 240L may be independently placed on the second surface 210-2, or may be independently embedded within the body part 210. Meanwhile, the connection line 240L may be at least part of a circuit included in the control apparatus 240. Further, the control apparatus 240 may include a battery for supplying power. Further, the control apparatus 240 may include a cover portion to cover the circuit and the battery for protection. In example embodiments, the control apparatus 240 may be connected to a plurality of shooting apparatuses 220 via connection lines 240L for transmitting and receiving data. For example, each of the plurality of shooting apparatuses 220 may transmit and/or receive data to/from the control apparatus 240 via a corresponding one of the connection lines 240L.

In an example embodiment, the substrate type sensor 200 may include a first region GA1 and a second region GA2 formed between the substrate type sensor 200 and the ring structure 300 with respect to the first direction D1. In an example embodiment, the first region GA1 is formed between the substrate type sensor 200 and the ring structure 300, and may be formed in one direction based on the first direction D1. Further, the second region GA2 may be formed between the substrate type sensor 200 and the ring structure 300, and may be formed in the other direction based on the first direction D1. For example, the first region GA1 and the second region GA2 may be located at opposite side of the substrate type sensor 200 in the first direction D1.

In an example embodiment, the first region GA1 and the second region GA2 may not overlap each other when viewed from the second direction D2. Specifically, each of the first region GA1 and the second region GA2 may indicate an area corresponding to the straight-line distance between the shooting apparatus 220 and the ring structure 300 with respect to the first direction D1.

In an example embodiment, the substrate type sensor 200 may include a light apparatus 230 disposed in the groove 210H. The light apparatus 230 may irradiate light in order for the light reflected from the ring structure 300 to be incident to the shooting apparatus 220. In example embodiments, the light apparatus 230 may be a plurality of light apparatuses 230.

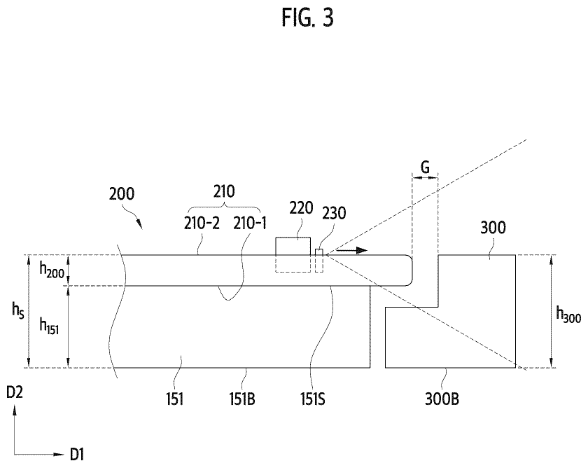

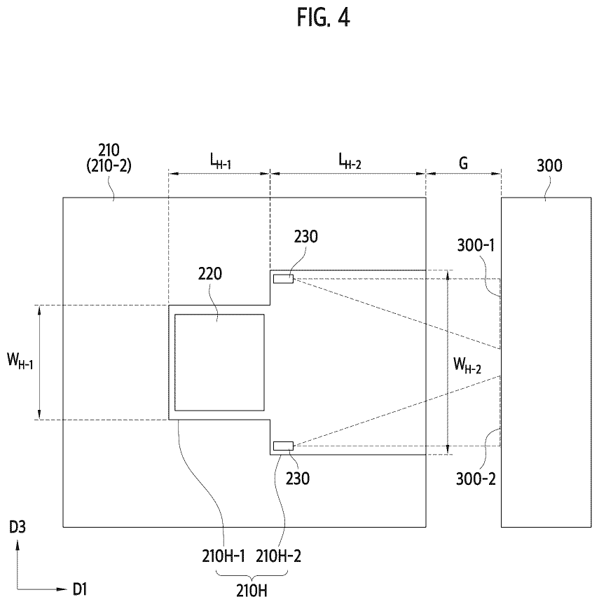

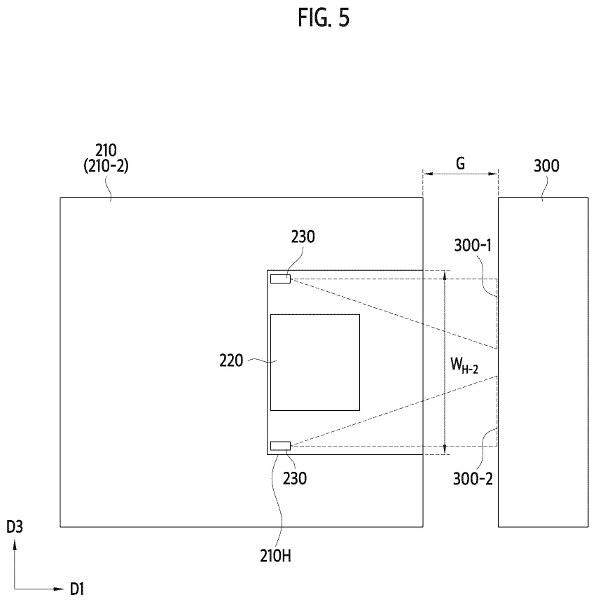

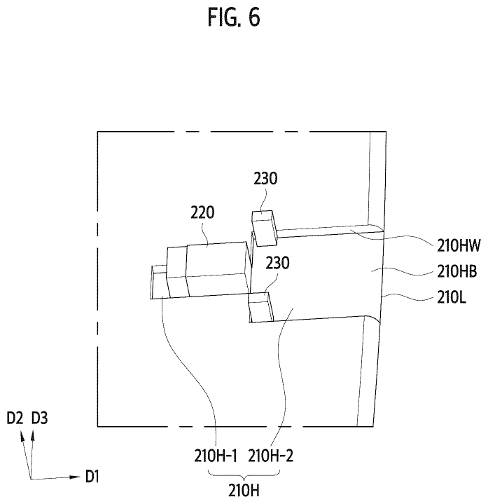

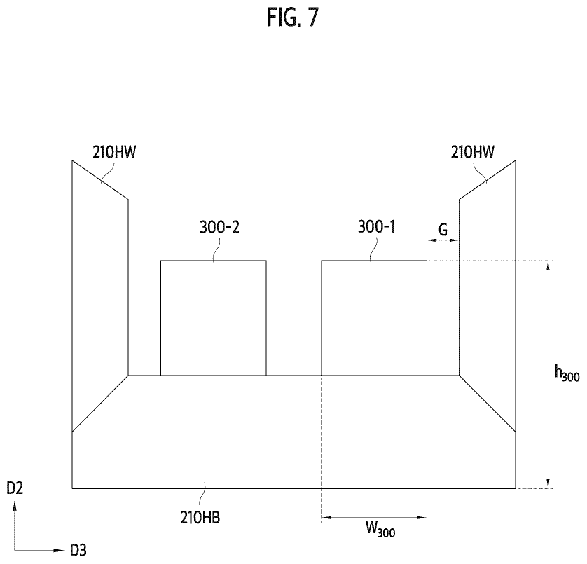

As an enlarged view of the portion A1 of FIG. 1, FIG. 3 is a cross-sectional view illustrating at least a portion of the substrate processing equipment 10 according to an example embodiment. As an enlarged view of the portion A2 of FIG. 2, FIG. 4 is a plan view illustrating at least a portion of the substrate type sensor 200 and at least a portion of the ring structure 300 according to an example embodiment. As an enlarged view of the portion A2 of FIG. 2, FIG. 5 is a plan view illustrating at least a portion of the substrate type sensor 200 and at least a portion of the ring structure 300 according to an example embodiment. FIG. 6 is a perspective view illustrating at least a portion of the substrate type sensor 200 according to an example embodiment. FIG. 7 illustrates a shooting result taken by the shooting apparatus 220 of the substrate type sensor 200 according to an example embodiment.

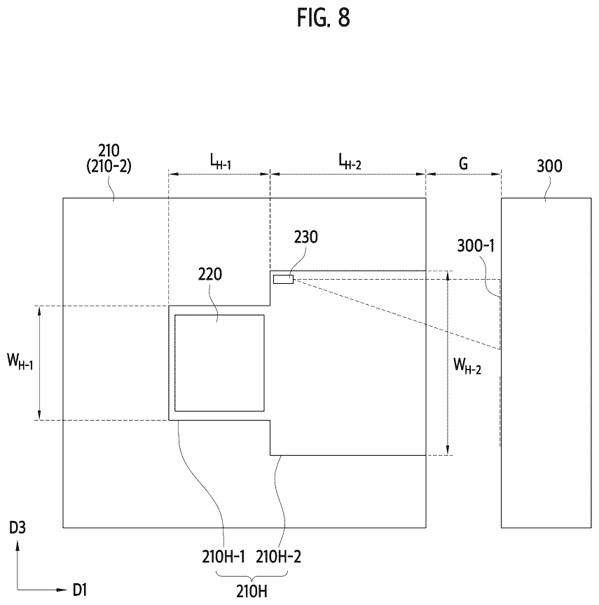

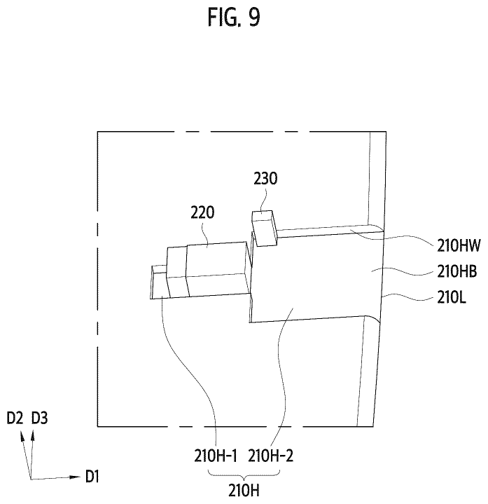

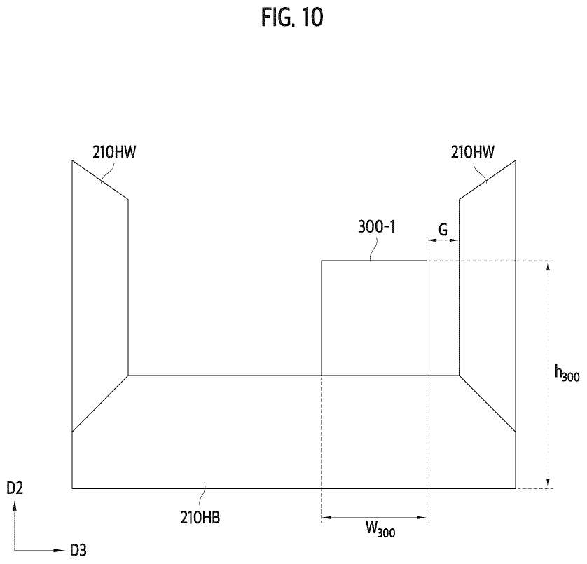

As an enlarged view of the portion A2 of FIG. 2, FIG. 8 is a plan view illustrating at least a portion of the substrate type sensor 200 and at least a portion of the ring structure 300 according to an example embodiment. FIG. 9 is a perspective view illustrating at least a portion of the substrate type sensor 200 according to an example embodiment. FIG. 10 illustrates a shooting result taken by the shooting apparatus 220 of the substrate type sensor 200 according to an example embodiment.

Referring to FIG. 2 to FIG. 10, the separation distance between the substrate type sensor 200 and the ring structure 300 of the first region GA1 and the separation distance between the substrate type sensor 200 and the ring structure 300 of the second region GA2 are the same, and the substrate type sensor 200 is aligned and placed on the receiving surface 151S.

In the substrate processing equipment 10 according to example embodiments, the chuck 151 may be provided with a flat supporting surface 151B that is an opposite surface with respect to the second direction D2. In an example embodiment, based on the second direction D2, a lower portion surface 300B placed at the lower end of the ring structure 300 and the supporting surface 151B may be placed on the same plane.

In an example embodiment, the light apparatus 230 may irradiate light at an angle between the first direction D1 and the second direction D2. Specifically, the angle toward the first direction D1, which is one of the angles at which the light apparatus 230 irradiates light, may indicate an angle toward the side of the ring structure 300. In other words, referring to FIG. 3, the angle facing the first direction D1 (e.g., shown with the dashed lines), which is one of the angles at which the light apparatus 230 irradiates light, may be an angle facing the +D1 direction.

In an example embodiment, the shooting apparatus 220 may shoot at least a portion of one side of the groove 210H and at least a portion of one side of the ring structure 300. The shooting apparatus 220 may achieve clearer shooting results through the light apparatus 230. Specifically, light irradiated from the light apparatus 230 may be reflected by the ring structure 300 and be incident on the shooting apparatus 220, and through the incident light, the shooting apparatus 220 may produce shooting results. However, the shooting apparatus 220 is simply positioned in the groove 210H so as to shoot at least a portion of one side of the ring structure 300, and it is not limited that the light apparatus 230 irradiates light only at an angle facing the first direction D1, which is an angle facing the side of the ring structure 300.

Referring to FIG. 2 to FIG. 4, when the separation distance between the substrate type sensor 200 and the ring structure 300 of the first region GA1 and the separation distance between the substrate type sensor 200 and the ring structure 300 of the second region GA2 are the same, the separation distance of the first region GA1 may be called a first separation distance G.

In an example embodiment, with respect to the second direction D2, the length h₃₀₀ of the ring structure 300 may be equal to or less than sum hₛ of the length h₁₅₁ of the chuck 151 and the length h200 of the substrate type sensor 200.

Referring to FIG. 4, in an example embodiment, the groove 210H may include a first part 210H-1 that is closer to the center of the substrate type sensor 200 based on the first direction D1, and a second part 210H-2 other than the first part 210H-1. In an example embodiment, the size and shape of the first part 210H-1 and the second part 210H-2 may be different.

In an example embodiment, at least a portion of the shooting apparatus 220 may be placed in the first part 210H-1. In an example embodiment, the entire shooting apparatus 220 may be placed in the first part 210H-1. Here, based on the third direction D3, the width W_{H-2} of the second part 210H-2 may be larger than the width W_{H-1} of the first part 210H-1. An appropriate angle of view may be secured to photograph at least a portion of one side of the ring structure 300 by placing the shooting apparatus 220 closer to the center of the substrate type sensor 200, and by making the width W_{H-2} of the second part 210H-2 larger than the width W_{H-1} of the first part 210H-1.

In an example embodiment, the length LH-1 of the first part 210H-1 and the length LH-2 of the second part 210H-2 may be the same with respect to the first direction D1. Further, in an example embodiment, the length LH-1 of the first part 210H-1 may be shorter than length LH-2 of the second part 210H-2 with respect to the first direction D1, and through this, an appropriate angle of view of the shooting apparatus 220 may be secured to photograph at least a portion of one side of the ring structure 300. In an example embodiment, the shooting apparatus 220 may be provided in the first part 210H-1 to be farther away from the ring structure 300, and the lighting apparatus 230 may be provided in the second part 210H-2 to be closer to the ring structure 300.

Referring to FIG. 5, in an example embodiment, the groove 210H may be in one form without being divided into the first part 210H-1 and the second part 210H-2 as illustrated in FIG. 4. For example, a width W_{H-2} of the groove 210H in the third direction D3 may be substantially uniform. In an example embodiment, the shooting apparatus 220 and the light apparatus 230 may be placed together in a single form of the groove 210H. In an example embodiment, when viewed from second direction D2, the shooting apparatus 220 and the light apparatus 230 may overlap at least partially.

In an example embodiment, referring to FIG. 4, the light apparatus 230 may not overlap the shooting apparatus 220 when viewed from the second direction D2. Additionally, referring to FIG. 5, the light apparatus 230 may overlap at least partially with the shooting apparatus 220 when viewed from the second direction D2.

In an example embodiment, there may be a plurality of light apparatuses 230. In an example embodiment, when viewed from the first direction D1, the shooting apparatus 220 may be arranged between the plurality of light apparatuses 230. The arrangement allows for high quality shooting results since the light is irradiated from the light apparatus 230 and the light reflected from the side of the ring structure 300 may smoothly enter the shooting apparatus 220.

In an example embodiment, each of the multiple light apparatuses 230 may have the same luminous intensity. Also, in this case, when viewed from the third direction D3, at least some areas may overlap each other. This minimizes differences in luminous intensity, resulting in high-quality shooting results.

In an example embodiment, the groove 210H may include a groove bottom surface 210HB that is parallel to the second surface 210-2 and a groove wall surface 210HW connected to both sides of the groove bottom surface 210HB. Specifically, the groove wall surface 210HW may be connected to both sides of the groove bottom surface 210HB along the third direction D3, and may be formed to extend in the second direction D2. In an example embodiment, the shooting apparatus 220 may photograph the groove wall surface 210HW and the groove bottom surface 210HB of the groove 210H.

In an example embodiment, the body part 210 may include an edge line 210L formed along an edge of the body part. In an example embodiment, with regard to the groove 210H, an edge of the groove bottom surface 210HB may be a part of the edge line 210L of the body part. In other words, when forming the groove 210H, processing may be performed so that the edge line 210L of the body part is maintained without being damaged. This may help align the substrate type sensor 200 so that the substrate is positioned correctly on the chuck 151.

In an example embodiment, the shooting apparatus 220 may shoot at least a portion of one side of the groove 210H and at least a portion of one side of the ring structure 300. Specifically, the shooting apparatus 220 may shoot the groove bottom surface 210HB and the groove wall surface 210HW, and shoot a portion of one side of the ring structure 300 (a portion 300-1 of the one side, and a portion 300-2 of the one side).

Referring to FIGS. 4 and 7, the plurality of light apparatuses 230 may irradiate light to a side of the ring structure 300 in the first direction D1, and the light reflected by the portion of the one side of the ring structure 300 (the portion 300-1 of the one side, and the portion 300-2 of the one side) may enter the shooting apparatus 220.

Meanwhile, in an example embodiment, in order to ensure high quality of shooting results, the substrate processing equipment 10 may not use any separate lighting other than the light apparatus 230 of the substrate type sensor 200. When there is separate lighting, there may be a lot of noise, which may degrade the quality of the resulting shot.

Referring back to FIG. 4 and FIG. 7, in the shooting results taken with the shooting apparatus 220 by the light apparatus 230, the portion of the one side of the ring structure 300 (the portion 300-1 of the one side, and the portion 300-2 of the one side) may be clearly seen as if protruding in the second direction D2.

Referring to FIG. 7, in an example embodiment, the length between one of the portions of the one side (the portion 300-1 of the one side, and the portion 300-2 of the one side) of the ring structure 300 and the groove wall surface 210HW based on the third direction D3 may indicate the separation distance G between the substrate type sensor 200 and the ring structure 300. Through the separation distance G, the control apparatus 240 may identify the degree to which the substrate type sensor 200 is biased. Through distance W₃₀₀ of one of the portions of the one side (the portion 300-1 of the one side, and the portion 300-2 of the one side) of the ring structure 300 based on the third direction D3, the control apparatus 240 may identify the degree to which the substrate type sensor 200 is biased. Further, the length h₃₀₀ between the groove bottom surface 210HB and one of the portions of the one side (the portion 300-1 of the one side, and the portion 300-2 of the one side) of the ring structure 300 based on the second direction D2 may be equal to the length h₃₀₀ of the ring structure 300 based on the second direction D2 described above. Through length h₃₀₀, the control apparatus 240 may quantitatively calculate the etched amount of the ring structure 300.

In an example embodiment, there may be one light apparatus 230, and the single light apparatus 230 may produce high quality photographic results as may the multiple light apparatuses 230. In other words, the number of light apparatuses 230 is not particularly limited.

For FIG. 8 to FIG. 10, the descriptions with respect to FIG. 4 to FIG. 7 may be referred to as long as the descriptions are not contradictory. For example, features that differ from the above descriptions are described, and duplicative descriptions are not repeated. Referring to FIG. 8 and FIG. 9, there may be a single light apparatus 230. In an example embodiment, referring to FIGS. 8 and 9, the light apparatus 230 may not overlap the shooting apparatus 220 when viewed from the second direction D2. Further, although the light apparatus 230 is not illustrated separately, as illustrated in FIG. 5, when viewed from the second direction D2, the shooting apparatus 220 and the light apparatus 230 may overlap at least in part.

Referring to FIG. 10, the shooting apparatus 220 may photograph the groove bottom surface 210HB and the groove wall surface 210HW, and may shoot the portion 300-1 of the one side of the ring structure 300. Unlike FIG. 7, FIG. 10 illustrates only one light apparatus 230, and thus the portion 300-1 of the one side of the ring structure 300 may appear in the photographing result. In an example embodiment, the length between the portion 300-1 of the one side of the ring structure 300 and the groove wall surface 210HW based on the third direction D3 may indicate the separation distance G between the substrate type sensor 200 and the ring structure 300. Through the separation distance G, the control apparatus 240 may identify the degree to which the substrate type sensor 200 is biased, and the control apparatus 240 may identify the degree to which the substrate type sensor 200 is lopsided through the distance W₃₀₀ of the portion 300-1 of the one side of the ring structure 300 based on the third direction D3. Further, the length h₃₀₀ between the groove bottom surface 210HB and the portion 300-1 of the one side of the ring structure 300 based on the second direction D2 may be equal to the length h₃₀₀ of the ring structure 300 based on the second direction D2 described above. Through the length h₃₀₀, even if there is only one light apparatus 230, the control apparatus 240 may quantitatively calculate the etched amount of the ring structure 300, as with the case where there are a plurality of light apparatuses 230.

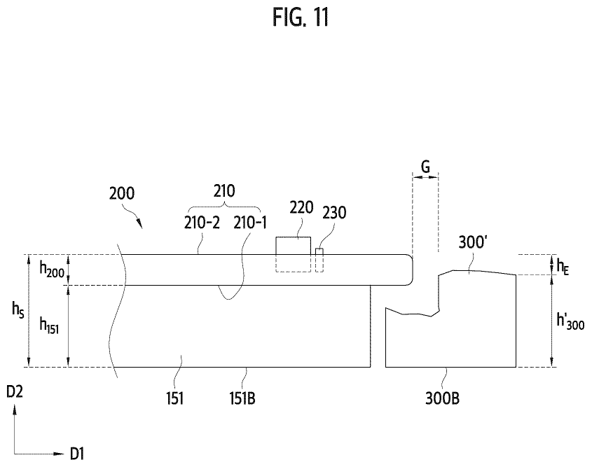

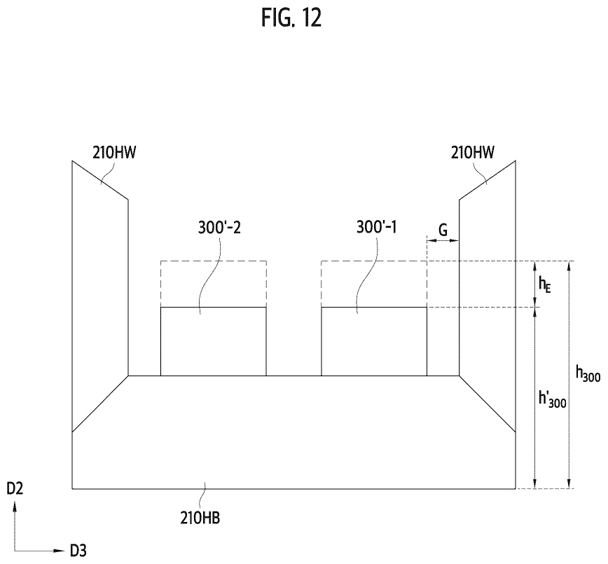

As an enlarged view of the portion A1 of FIG. 1, FIG. 11 is a cross-sectional view illustrating at least a portion of the substrate processing equipment 10. FIG. 12 illustrates a result of photographing using the substrate type sensor 200 according to one embodiment of the present disclosure.

FIG. 11 and FIG. 12 illustrate that the substrate is removed from the substrate processing equipment 10, and the substrate type sensor 200 is mounted on the receiving surface 151S again after the etching process on the substrate is performed (including etching process is repeated for one substrate or for a plurality of substrates). Further, the ring structure 300 may be etched to become an etched ring structure 300′. Further, FIG. 11 and FIG. 12 are drawings illustrating that since the separation distance between the substrate type sensor 200 and the ring structure 300 of the first region GA1 and the separation distance between the substrate type sensor 200 and the ring structure 300 of the second region GA2 are the same, the substrate type sensor 200 is aligned and placed on the receiving surface 151S.

Referring to FIG. 12, which is the result of photographing a portion of one side (a portion 300′-1 of the one side and a portion 300′-2 of the one side) of an etched ring structure 300′ using the shooting apparatus 220 in the same manner as described above, the length h′300 of the etched ring structure 300′ is shorter than the length h₃₀₀ of the ring structure 300 before etching based on the second direction D2. As such, with respect to before etching the substrate and after etching the substrate, the control apparatus 240 may calculate the difference in the length (the length h₃₀₀ and the length h′300) along the second direction D2 of the ring structure 300, and according thereto, derive the etched length h_{E} and derive the etched amount of the ring structure 300. Here, the separation distance G between the substrate type sensor 200 and the ring structure 300 may be the same based on the third direction D3 before and after etching of the substrate.

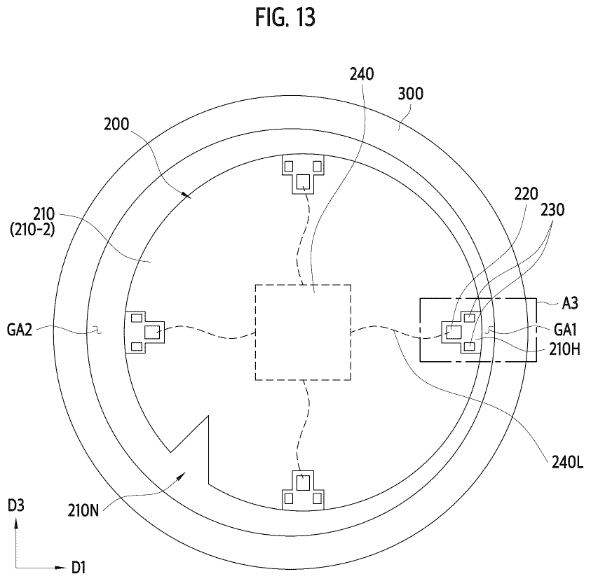

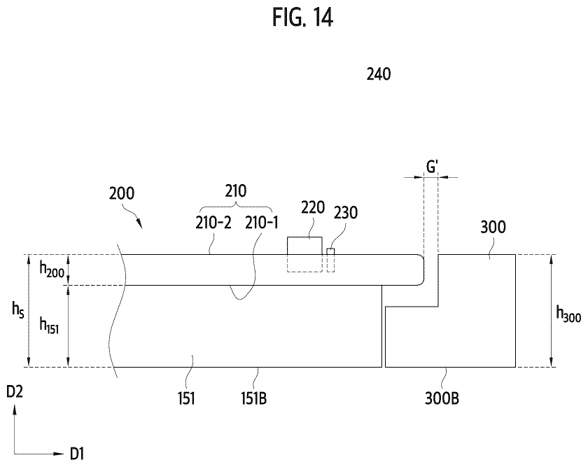

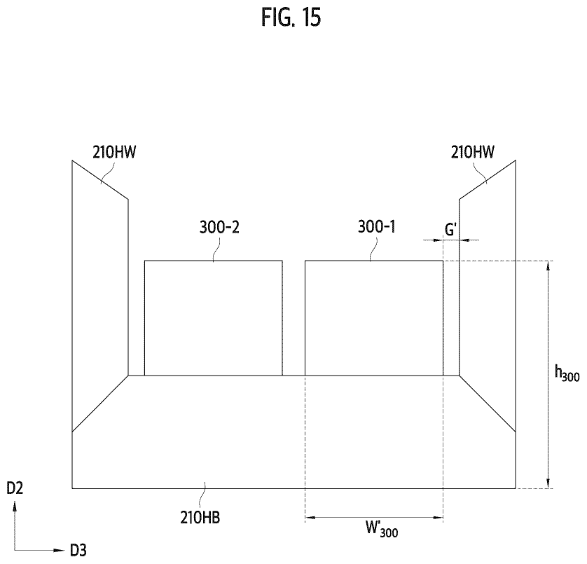

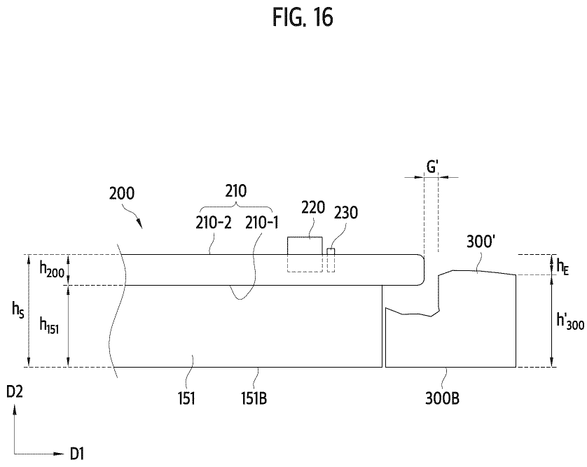

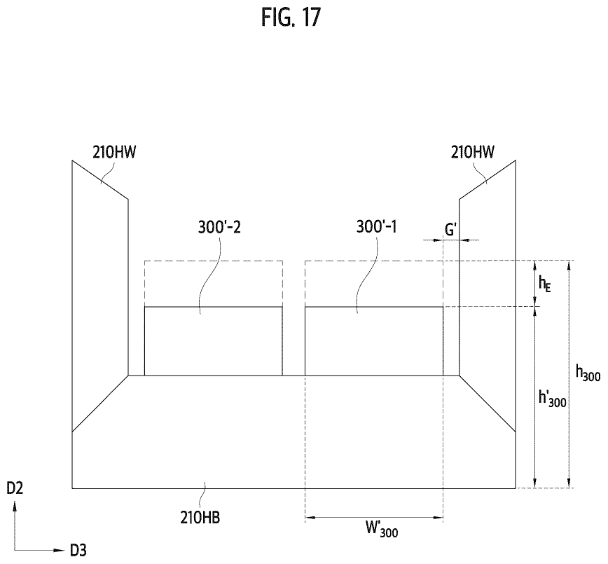

FIG. 13 is a plan view illustrating at least a portion of the substrate type sensor 200 and at least a portion of the ring structure 300 according to an example embodiment. As an enlarged view of the portion A1 of FIG. 1 and a cross-sectional view of the A3 portion of FIG. 13 in the second direction D2, FIG. 14 is a cross-sectional view illustrating at least a portion of the substrate processing equipment 10 according to an example embodiment. FIG. 15 illustrates a shooting result taken by the substrate type sensor 200 according to an example embodiment. As an enlarged view of the portion A1 of FIG. 1 and a cross-sectional view of the A3 portion of FIG. 13 in the second direction D2, FIG. 16 is a cross-sectional view illustrating at least a portion of the substrate processing equipment 10 according to an example embodiment. FIG. 17 illustrates a result of photographing using the substrate type sensor 200 according to an example embodiment. Referring to FIG. 13 to FIG. 17, based on the first region GA1, the substrate is placed to the right in the drawing in the +first direction (+D1). Further, FIG. 15 and FIG. 17 specifically illustrate shooting results taken by the shooting apparatus 220 of the substrate type sensor 200.

Referring to FIG. 13 and FIG. 14, the separation distance between the substrate type sensor 200 and the ring structure 300 of the first region GA1 and the separation distance between the substrate type sensor 200 and the ring structure 300 of the second region GA2 may be different. Here, the separation distance of the first region GA1 may be called a second separation distance G′. Also, at this time, the second separation distance G′ (that is, on the right side) may be shorter than the first separation distance G described above.

Referring to FIG. 15, the second separation distance G′ is shorter than the first separation distance G described above, based on the third direction D3, the distance W′300 of one of the portions of the one side of the ring structure 300 (the portion 300-1 of the one side, and the portion 300-2 of the one side) may be greater than the distance W₃₀₀ of one of the portions of the one side of the ring structure 300 (the portion 300-1 of the one side, and the portion 300-2 of the one side) when the substrate type sensor 200 is aligned and placed on the receiving surface 151S. In other words, when the separation distance (for example, the second separation distance G′) between the substrate type sensor 200 and the ring structure 300 based on the first region GA1 is smaller than the separation distance (for example, the first separation distance G) between the substrate type sensor 200 and the ring structure 300 when the substrate type sensor 200 is aligned and placed on the receiving surface 151S, this may indicate that the substrate type sensor 200 is shifted to the right compared to the aligned state. Further, when the distance W′300 of one of the portions of the one side (the portion 300-1 of the one side, and the portion 300-2 of the one side) of the ring structure 300 based on the first region GA is greater than the distance W₃₀₀ of one of the portions of the one side of the ring structure 300 (the portion 300-1 of the one side, and the portion 300-2 of the one side) when the substrate type sensor 200 is aligned and placed on the receiving surface 151S, this may indicate that the substrate type sensor 200 is shifted to the right compared to the aligned state.

In an example embodiment, the control apparatus 240 may calculate the difference between the first separation distance G and the second separation distance G′. Further, as described above, when the second separation distance G′ is smaller than the first separation distance G, the control apparatus 240 may determine that the substrate type sensor 200 is shifted to the right compared to the aligned state, and when the substrate is later placed on the receiving surface 151S, the control apparatus 240 may move the substrate to the left (in other words, −first direction (−D1) in the drawing) by the difference between the first separation distance G and the second separation distance G′ described above. Specifically, when the substrate is later placed on the receiving surface 151S, the control apparatus 240 may move the substrate toward the center by the difference between the first separation distance G and the second separation distance G′ described above.

In an example embodiment, when the distance W′₃₀₀ of one of the portions of the one side of the ring structure 300 (the portion 300-1 of the one side, and the portion 300-2 of the one side) when the substrate type sensor 200 is placed on the receiving surface 151S in a unilateral state is greater than the distance W₃₀₀ of one of the portions of the one side of the ring structure 300 (the portion 300-1 of the one side, and the portion 300-2 of the one side) when the substrate type sensor 200 is aligned and placed on the receiving surface 151S, the control apparatus 240 may move the substrate to the left (in other words, in the −first direction (−D1) in the drawing) by the difference in the distance (the distance W′300, and the distance W₃₀₀) described above when the substrate is later settled on the receiving surface 151S. Specifically, the control apparatus 240 may move the substrate toward the center by the difference in distance (the distance W′300, and the distance W₃₀₀) described above when the substrate is later placed on the receiving surface 151S.

FIG. 16 and FIG. 17 illustrate that the substrate is removed from the substrate processing equipment 10, and the substrate type sensor 200 is mounted on the receiving surface 151S again after the etching process is performed on the substrate (including that the etching process is repeated for one substrate or for a plurality of substrates). Here, without moving the substrate toward the center by the difference between the first separation distance G and the second separation distance G′ so that the substrate type sensor 200 is aligned, the control apparatus 240 may mount the substrate type sensor 200 on the receiving surface 151S to achieve the second separation distance G′ before the etching process. In other words, FIG. 17 may be based on the separation distance (for example, the second separation distance G′) between the substrate type sensor 200 and the ring structure 300 in FIG. 14 being the same.

In an example embodiment, referring to FIG. 17, which is the result of photographing a portion of the one side (the portion 300′-1 of the one side and the portion 300′-2 of the one side) of the etched ring structure 300′ using the shooting apparatus 220 in the same manner as described above, based on the second direction D2, the length h′300 of the etched ring structure 300′ is shorter than the length h₃₀₀ of the ring structure 300 before etching. As such, with respect to before etching the substrate and after etching the substrate, the control apparatus 240 may calculate the difference in the length (the length h₃₀₀ and the length h′₃₀₀) along the second direction D2 of the ring structure 300, and according thereto, derive the etched length h_{E} and derive the etched amount of the ring structure 300. Here, the separation distance (for example, the second separation distance G) before and after etching the substrate between the substrate type sensor 200 and the ring structure 300 may be the same based on the third direction D3. Through this, even though the substrate type sensor 200 is unilateral, when the shooting results are viewed, the groove wall surface 210HW and the groove bottom surface 210HB of the groove 210H do not change, and thus the etched amount of the ring structure 300 may be measured without aligning the substrate type sensor 200.

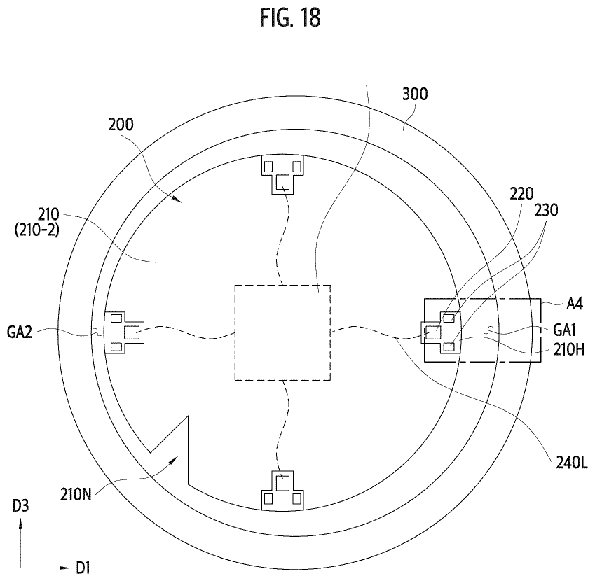

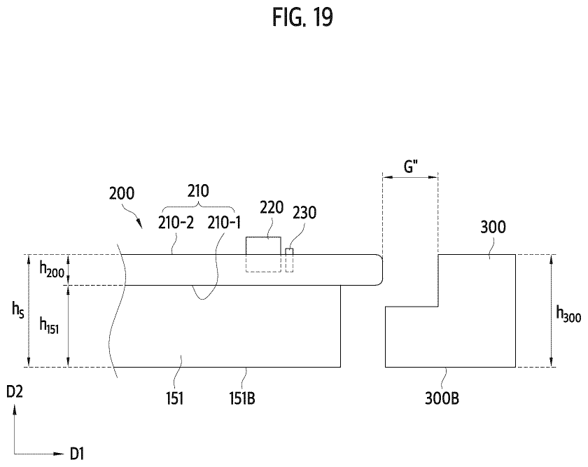

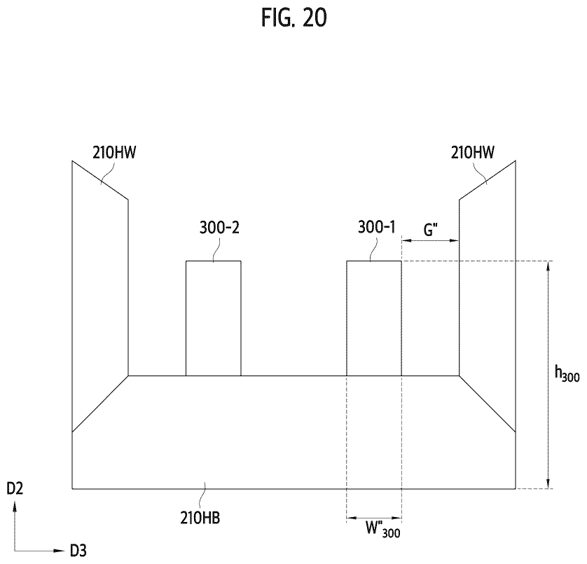

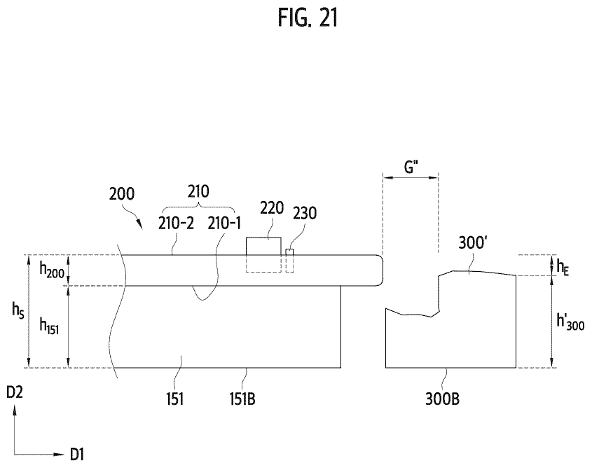

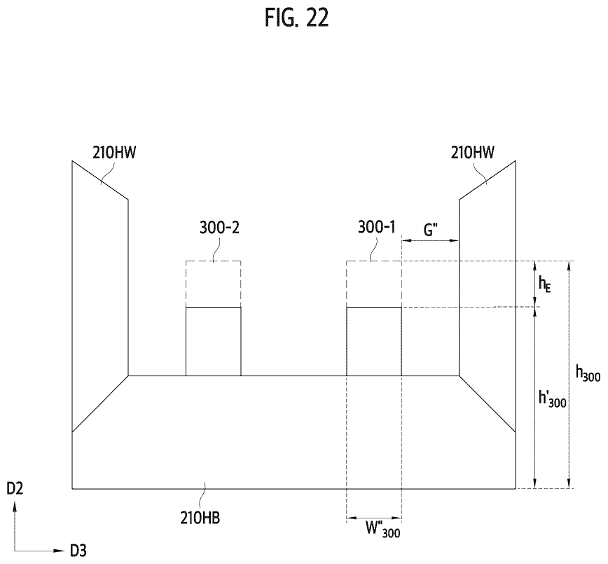

FIG. 18 is a plan view illustrating at least a portion of the substrate type sensor 200 and at least a portion of the ring structure 300 according to an example embodiment. As an enlarged view of the portion A1 of FIG. 1 and a cross-sectional view of the A4 section of FIG. 18 in the second direction D2, FIG. 19 is a cross-sectional view illustrating at least a portion of the substrate processing equipment 10 according to an example embodiment. FIG. 20 illustrates a result of photographing using the substrate type sensor 200 according to an example embodiment. As an enlarged view of the portion A1 of FIG. 1 and a cross-sectional view of the A4 section of FIG. 18 in the second direction D2, FIG. 21 is a cross-sectional view illustrating at least a portion of the substrate processing equipment 10 according to an example embodiment. FIG. 22 illustrates a photographing result taken by the substrate type sensor 200 according to an example embodiment. Referring to FIG. 18 to FIG. 22, based on the first region GA1, the substrate is placed to the left in the drawing in the −first direction (−D1). Further, FIG. 20 and FIG. 22 specifically illustrate shooting results taken by the shooting apparatus 220 of the substrate type sensor 200.

Referring to FIG. 18 and FIG. 19, the separation distance between the substrate type sensor 200 and the ring structure 300 of the first region GA1 and the separation distance between the substrate type sensor 200 and the ring structure 300 of the second region GA2 may be different. Here, the separation distance of the first region GA may be called a second separation distance G″. Further, at this time, the second separation distance G″ (that is, on the right side) may be longer than the first separation distance G described above.

Referring to FIG. 20, the second separation distance G″ is longer than the first separation distance G described above, the distance W″300 of one of the portions of the one side (the portion 300-1 of the one side, and the portion 300-2 of the one side) of the ring structure 300 based on the third direction D3 may be less than the distance W₃₀₀ of one of the portions of the one side of the ring structure 300 (the portion 300-1 of the one side, and the portion 300-2 of the one side) when the substrate type sensor 200 described above is aligned and placed on the receiving surface 151S. In other words, when the separation distance (for example, the second separation distance G″) between the substrate type sensor 200 and the ring structure 300 based on the first region GA1 is greater than the separation distance (for example, the first separation distance G) between the substrate type sensor 200 and the ring structure 300 when the substrate type sensor 200 is aligned and placed on the receiving surface 151S, this may indicate that the substrate type sensor 200 is shifted to the left compared to the aligned state. Further, when the distance W″300 of one of the portions of the one side (the portion 300-1 of the one side, and the portion 300-2 of the one side) of the ring structure 300 based on the first region GA1 is less than the distance W₃₀₀ of one of the portions of the one side of the ring structure 300 (the portion 300-1 of the one side, and the portion 300-2 of the one side) when the substrate type sensor 200 is aligned and placed on the receiving surface 151S, this may indicate that the substrate type sensor 200 is shifted to the left compared to the aligned state.

In an example embodiment, the control apparatus 240 may calculate the difference between the first separation distance G and the second separation distance G″. Further, as described above, when the second separation distance G″ is greater than the first separation distance G, the control apparatus 240 may determine that the substrate type sensor 200 is shifted to the left compared to the aligned state, and when the substrate is later placed on the receiving surface 151S, the control apparatus 240 may move the substrate to the right (in other words, +first direction (+D1) in the drawing) by the difference between the first separation distance G and the second separation distance G″ described above. Specifically, when the substrate is later placed on the receiving surface 151S, the control apparatus 240 may move the substrate away from the center by the difference between the first separation distance G and the second separation distance G″ described above.

In an example embodiment, when the distance W″300 of one of the portions of the one side of the ring structure 300 (the portion 300-1 of the one side, and the portion 300-2 of the one side) when the substrate type sensor 200 is placed on the receiving surface 151S in a unilateral state is less than the distance W₃₀₀ of one of the portions of the one side of the ring structure 300 (the portion 300-1 of the one side, and the portion 300-2 of the one side) when the substrate type sensor 200 is aligned and placed on the receiving surface 151S, the control apparatus 240 may determine that the substrate type sensor 200 is shifted to the left compared to the aligned state, and when the substrate is later placed on the receiving surface 151S, the control apparatus 240 may move the substrate to the right (in other words, in the +first direction (+D1) in the drawing) by the difference in the aforementioned distance (the distance W″₃₀₀, and the distance W₃₀₀). Specifically, the control apparatus 240 may move the substrate away from the center by the difference in distance (the distance W″₃₀₀, and the distance W₃₀₀) described above when the substrate is later settled on the receiving surface 151S.

FIG. 21 and FIG. 22 illustrate that the substrate is removed from the substrate processing equipment 10, and the substrate type sensor 200 is mounted on the receiving surface 151S again after the etching process is performed on the substrate (including that the etching process is repeated for one substrate or for a plurality of substrates). Here, without moving the substrate toward the center by the difference between the first separation distance G and the second separation distance G″ so that the substrate type sensor 200 is aligned, the control apparatus 240 may mount the substrate type sensor 200 on the receiving surface 151S to achieve the second separation distance G″ before the etching process. In other words, FIG. 22 may be based on that the separation distance (for example, the second separation distance G″) between the substrate type sensor 200 and the ring structure 300 in FIG. 20 is the same.

In an example embodiment, referring to FIG. 22, which is the result of photographing a portion of the one side (the portion 300′-1 of the one side and the portion 300′-2 of the one side) of the etched ring structure 300′ using the shooting apparatus 220 in the same manner as described above, based on the second direction D2, the length h′₃₀₀ of the etched ring structure 300′ is shorter than the length h₃₀₀ of the ring structure 300 before etching. As such, with respect to before etching the substrate and after etching the substrate, the control apparatus 240 may calculate the difference in the length (the length h₃₀₀ and the length h′₃₀₀) along the second direction D2 of the ring structure 300, and according thereto, derive the etched length h_{E} and derive the etched amount of the ring structure 300. Here, the separation distance (for example, the second separation distance G″) between the substrate type sensor 200 and the ring structure 300 before and after etching the substrate may be the same based on the third direction D3. Through this, even though the substrate type sensor 200 is unilateral, when the shooting results are viewed, the groove wall surface 210HW and the groove bottom surface 210HB of the groove 210H do not change, and thus the etched amount of the ring structure 300 may be measured without aligning the substrate type sensor 200.

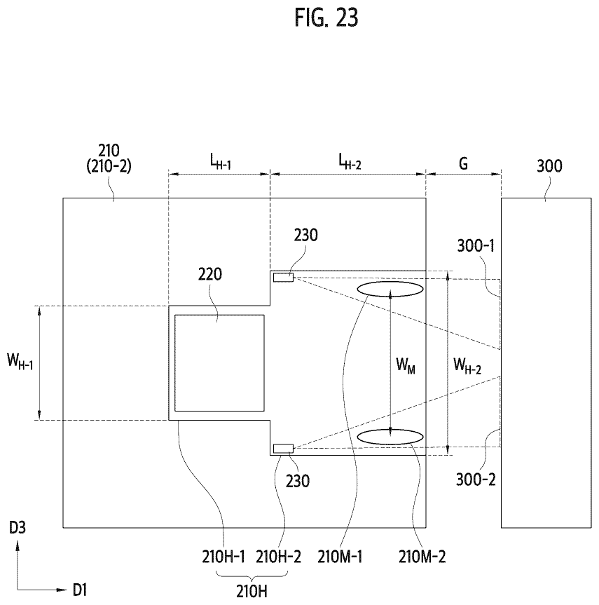

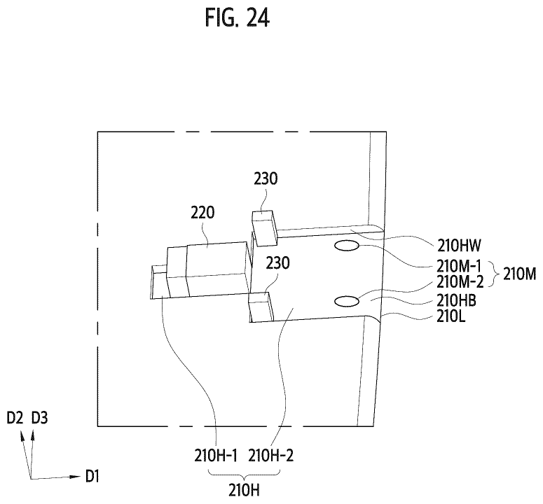

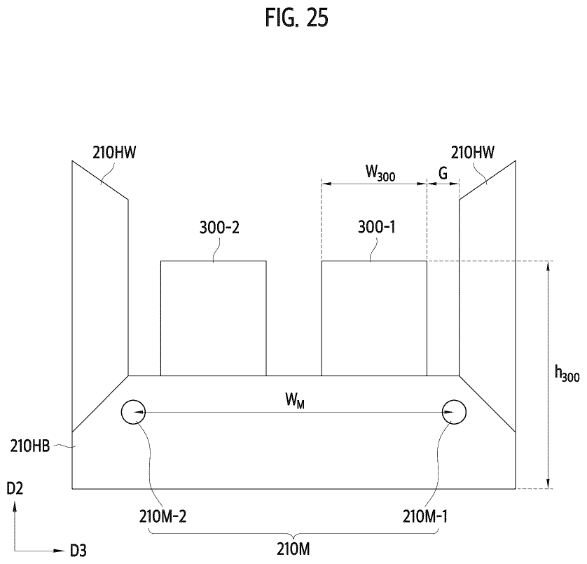

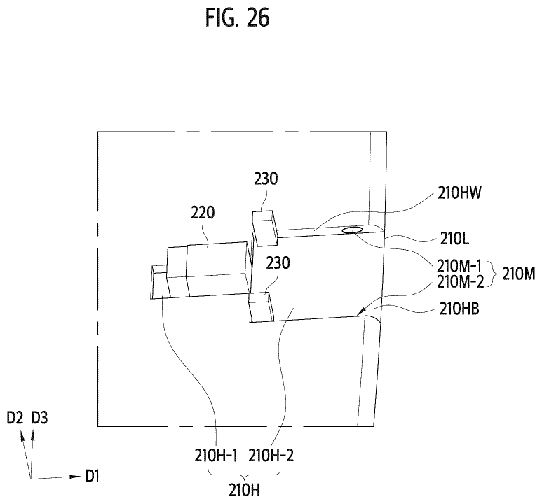

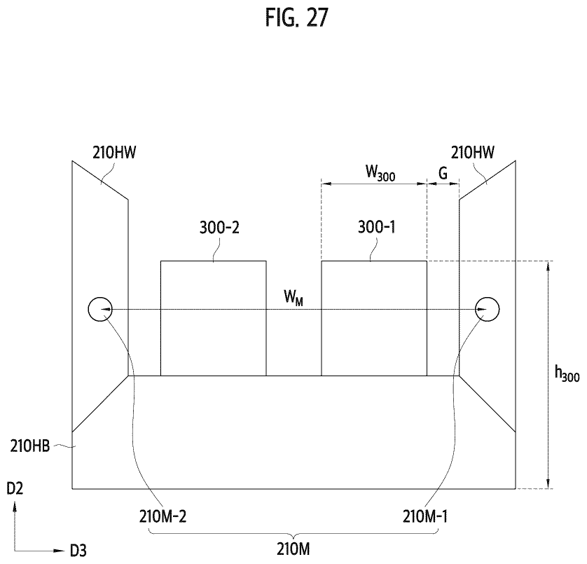

As an enlarged view of the portion A2 of FIG. 2, FIG. 23 is a plan view illustrating at least a portion of the substrate type sensor 200 and at least a portion of the ring structure 300 according to an example embodiment. FIG. 24 is a perspective view illustrating at least a portion of the substrate type sensor 200 according to an example embodiment. FIG. 25 illustrates a photographing result taken by the substrate type sensor 200 according to an example embodiment. FIG. 26 is a perspective view illustrating at least a portion of the substrate type sensor 200 according to an example embodiment. FIG. 27 illustrates a result of photographing using the substrate type sensor 200 according to an example embodiment. FIG. 23 to FIG. 27 are drawings illustrating that since the separation distance between the substrate type sensor 200 and the ring structure 300 of the first region GA1 and the separation distance between the substrate type sensor 200 and the ring structure 300 of the second region GA2 are the same, the substrate type sensor 200 is aligned and placed on the receiving surface 151S. Further, FIG. 25 and FIG. 27 specifically illustrate the shooting results taken by the shooting apparatus 220 of the substrate type sensor 200.

In an example embodiment, the substrate type sensor 200 may include reference marks 210M disposed in the groove 210H. In an example embodiment, the reference marks 210M may be photographed by the shooting apparatus 220. In other words, the reference marks 210M may appear in the shooting results.

In an example embodiment, the reference marks 210M may include a first reference mark 210M-1 and a second reference mark 210M-2 separated from each other by a predetermined separation distance WM in the third direction D3.

Referring to FIG. 23 to FIG. 25, the reference marks 210M may be formed on the groove bottom surface 210HB. Specifically, the reference marks 210M may be formed on the groove bottom surface 210HB of the second part 210H-2. Through this, the reference marks 210M may appear in the shooting results. Meanwhile, since the separation distance WM between the first reference mark 210M-1 and the second reference mark 210M-2 in the third direction D3 does not change in value, based thereon, the length h₃₀₀ of the ring structure 300 along the second direction D2 may be calculated. The calculations of the following process may be performed by the control apparatus 240.

For example, through the shooting results, based on the state where the substrate type sensor 200 is aligned and placed on the receiving surface 151S, the ratio of the separation distance WM between the first reference mark 210M-1 and the second reference mark 210M-2 in third direction D3 to the length h₃₀₀ of the ring structure 300 in second direction D2 (WM/h₃₀₀ or h₃₀₀/WMI) may be calculated.

Meanwhile, when the substrate type sensor 200 is not aligned and is placed on the receiving surface 151S in a one-sided manner, for example, to the right, the ratio of separation distance WM between the first reference mark 210M-1 and the second reference mark 210M-2 in the third direction D3 to the length h₃₀₀ of the ring structure 300 in the second direction D2 (WM/h₃₀₀ or h₃₀₀/WMI) may be calculated.

Here, since the separation distance WM between the first reference mark 210M-1 and the second reference mark 210M-2 in the third direction D3 is predetermined and does not change, when the substrate type sensor 200 is unilaterally placed on the right side, the length h₃₀₀ of the ring structure 300 in the second direction D2 may be calculated without measuring the length h₃₀₀ of the ring structure 300 in the second direction D2 through the ratio calculation.

Referring to FIG. 26 and FIG. 27, the reference marks 210M may be formed on the groove wall surface 210HW. Specifically, the reference marks 210M may be formed on the groove wall surface 210HW of the second part 210H-2. Through this, the reference mark 210M may appear in the shooting results. Meanwhile, since the value of the separation distance WM between the first reference mark 210M-1 and the second reference mark 210M-2 in the third direction D3 does not change, the length h₃₀₀ of the ring structure 300 in the second direction D2 may be calculated based on the value. The above descriptions may be referred to for the calculation method as long as the descriptions are not contradictory. For example, features that differ from the above descriptions are described, and duplicative descriptions are not repeated.

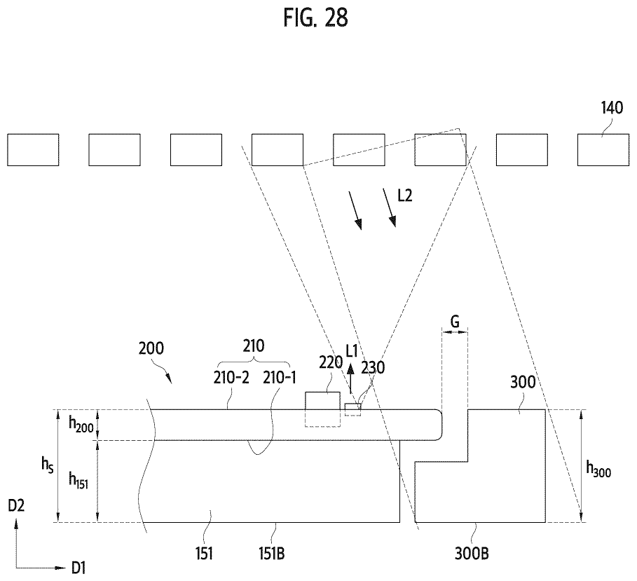

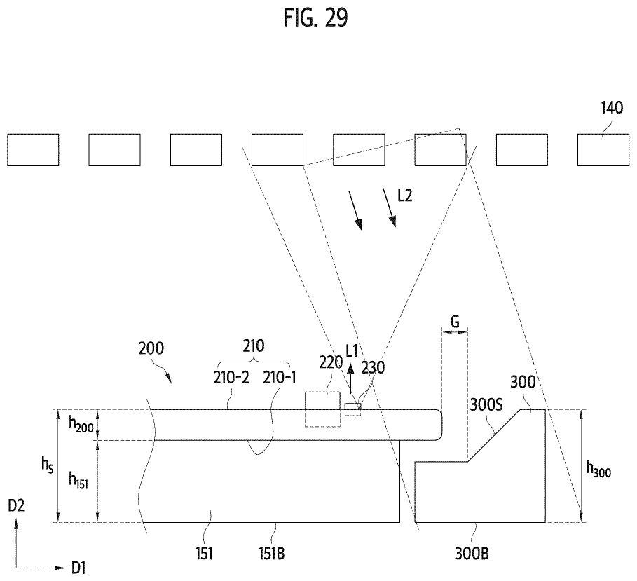

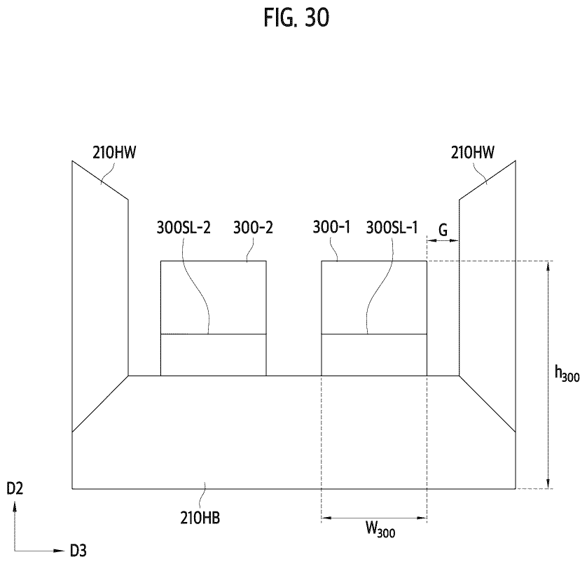

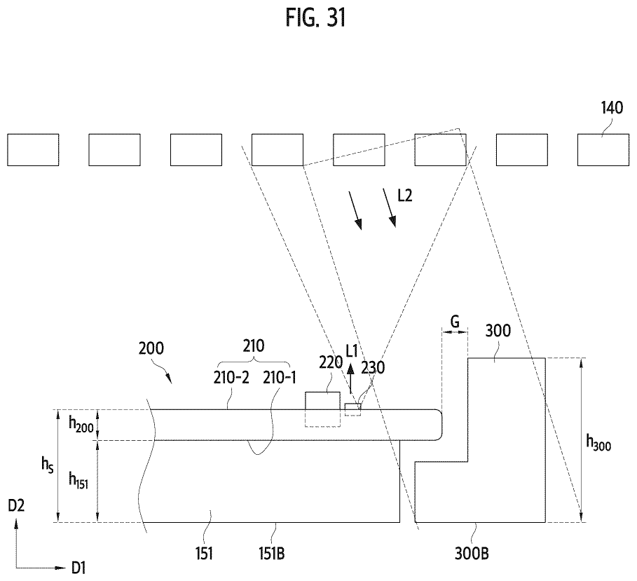

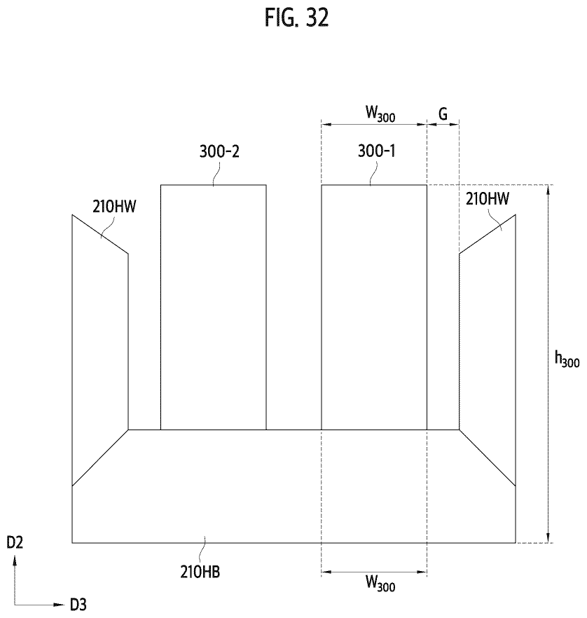

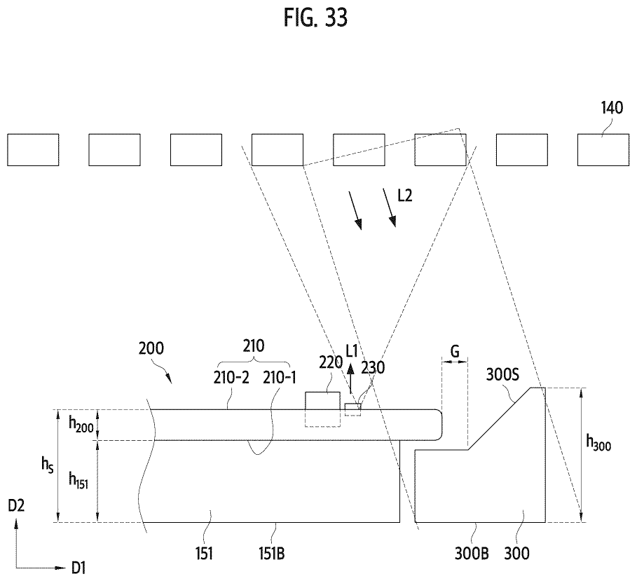

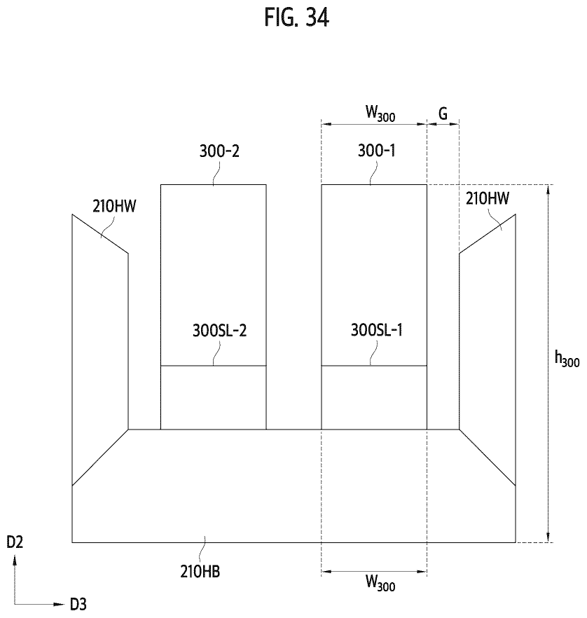

As an enlarged view of the portion A1 of FIG. 1, FIG. 28 is a cross-sectional view illustrating at least a portion of the substrate processing equipment 10 according to an example embodiment. As an enlarged view of the portion A1 of FIG. 1, FIG. 29 is a cross-sectional view illustrating at least a portion of the substrate processing equipment 10 according to an example embodiment. FIG. 30 illustrates a result of photographing using the substrate type sensor 200 according to an example embodiment. As an enlarged view of the portion A1 of FIG. 1, FIG. 31 is a cross-sectional view illustrating at least a portion of the substrate processing equipment 10 according to an example embodiment. FIG. 32 illustrates a result of photographing using the substrate type sensor 200 according to an example embodiment. As an enlarged view of the portion A1 of FIG. 1, FIG. 33 is a cross-sectional view illustrating at least a portion of the substrate processing equipment 10 according to an example embodiment. FIG. 34 illustrates a result of photographing using the substrate type sensor 200 according to according to an example embodiment. FIG. 28 to FIG. 34 illustrate that the light apparatus 230 irradiates light at an angle toward the second direction D2 (specifically, +second direction (+D2)). Further, FIG. 30, FIG. 32 and FIG. 34 specifically illustrate the shooting results taken by the shooting apparatus 220 of the substrate type sensor 200.

In an example embodiment, the light apparatus 230 may irradiate light at an angle between the first direction D1 and the second direction D2 as described above. Specifically, the angle at which the light apparatus 230 irradiates light, which is one of the angles facing the second direction D2, may indicate the angle facing the shower head 140. In other words, referring to FIG. 28, unlike what is illustrated in FIG. 3, the angle facing the second direction D2, which is one of the angles at which the light apparatus 230 irradiates light, may be an angle facing the +D2 direction.

In an example embodiment, the light apparatus 230 may irradiate light between an angle toward the first direction D1 and an angle toward the second direction D2, and irradiate light beyond the angle toward the first direction D1. Light L1 irradiated at this angle may be incident on the shower head 140, the light L1 incident on the shower head 140 becomes reflected light L2 and may be incident on at least a portion of one side of the groove 210H and at least a portion of one side of the ring structure 300, and the light that is reflected again may enter the shooting apparatus 220. The light apparatus 230 may irradiate light between an average angle of the angle toward the first direction D1 and the angle toward the second direction D2 and an angle toward the second direction 2.

Referring to FIG. 29 and FIG. 30, in the first direction D1, at least a portion of the surface of the ring structure 300 facing the substrate type sensor 200 may be an inclined surface 300S. In other words, the ring structure 300 may include the inclined surface 300S. In this case, the light apparatus 230 irradiating light between an angle toward the first direction D1 and an angle toward the second direction D2, and irradiating light beyond the angle toward the first direction D1 may be more advantageous to obtain high quality shooting results. The light apparatus 230 may irradiate light between an average angle of the angle toward the first direction D1 and the angle toward the second direction D2 and an angle toward the second direction D2. Further, referring to FIG. 30, if the light apparatus 230 irradiates light at an angle within the aforementioned range, it may be advantageous to make the boundary (boundary 300SL-1, and boundary 300SL-2) of the inclined surface 300S appear in the photographing result.

Referring to FIG. 31 and FIG. 32, in an example embodiment, based on the second direction D2, the length h₃₀₀ of the ring structure 300 may be greater than the sum hₛ of the length h₁₅₁ of the chuck 151 and the length h200 of the substrate type sensor 200. In this case, the light apparatus 230 irradiating light between an angle toward the first direction D1 and an angle toward the second direction D2, and irradiating light beyond the angle toward the first direction D1 may be more advantageous in obtaining high quality shooting results. The light apparatus 230 may irradiate light between an average angle of the angle toward the first direction D1 and the angle toward the second direction D2 and an angle toward the second direction D2. In this case, when the light apparatus 230 irradiates light at an angle toward the first direction D1, the photographing result may not fully show the extension along the second direction D2 of a portion of the one side of the ring structure 300 (the portion 300-1 of the one side, and the portion 300-2 of the one side). Therefore, in order to ensure that the extended shape along the second direction D2 of the portion of the one side (the portion 300-1 of the one side, and the portion 300-2 of the one side) of the ring structure 300 is fully visible in the shooting results, the light irradiation angle of the light apparatus 230 may be changed.

Referring to FIG. 33 and FIG. 34, in an example embodiment, at least a portion of the surface of the ring structure 300 facing the substrate type sensor 200 may be the inclined surface 300S in the first direction D1, and based on the second direction D2, the length h₃₀₀ of the ring structure 300 may be greater than the sum hₛ of the length h₁₅₁ of the chuck 151 and the length h200 of the substrate type sensor 200. In this case, the light apparatus 230 irradiating light between an angle toward the first direction D1 and an angle toward the second direction D2, and irradiating light beyond the angle toward the first direction D1 may be more advantageous in obtaining high quality shooting results. The light apparatus 230 may irradiate light between an average angle of the angle toward the first direction D1 and the angle toward the second direction D2 and an angle toward the second direction.

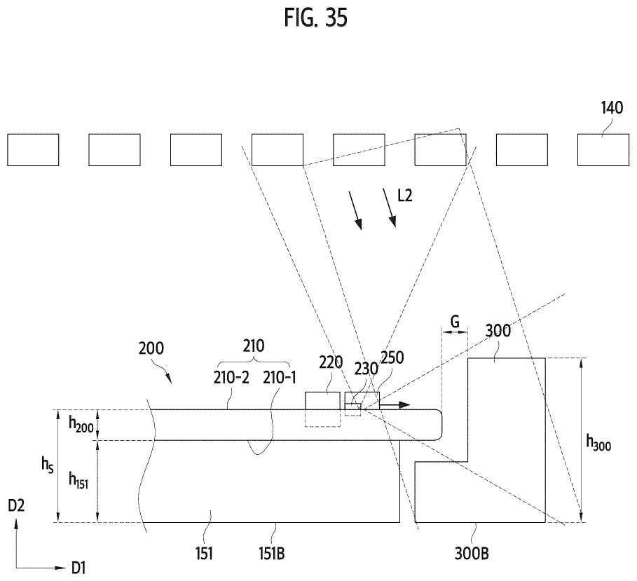

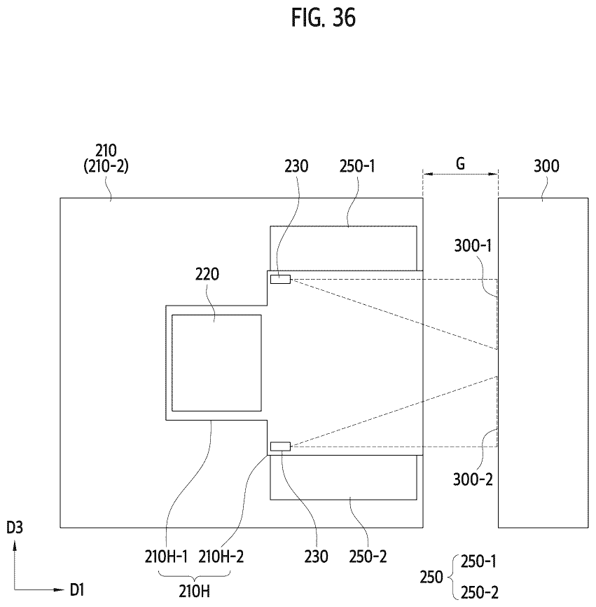

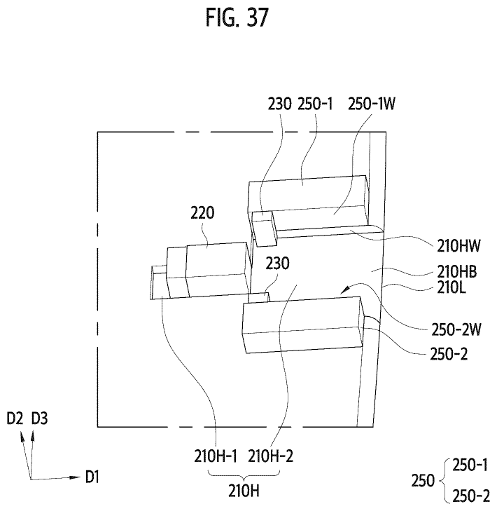

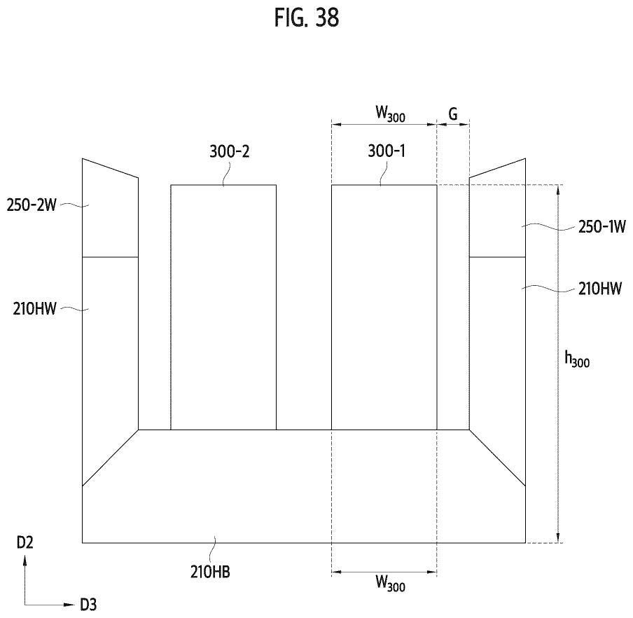

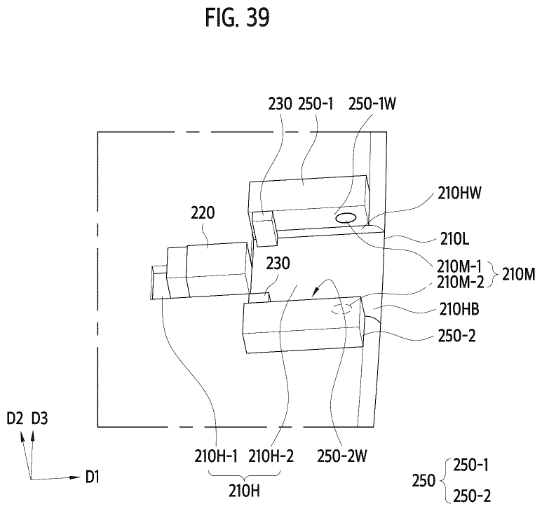

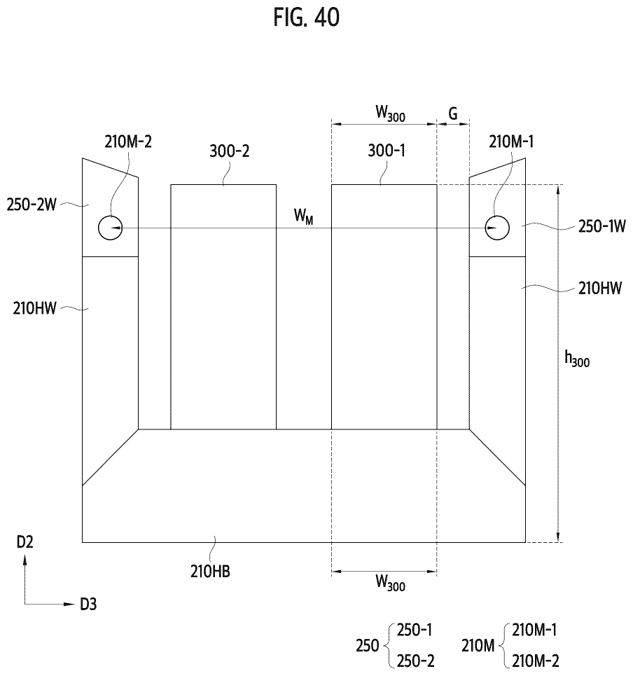

As an enlarged view of the portion A1 of FIG. 1, FIG. 35 is a cross-sectional view illustrating at least a portion of the substrate processing equipment 10 according to an example embodiment. As an enlarged view of the portion A2 of FIG. 2, FIG. 36 is a plan view illustrating at least a portion of the substrate type sensor 200 and at least a portion of the ring structure 300 according to an example embodiment. FIG. 37 is a perspective view illustrating at least a portion of the substrate type sensor 200 according to an example embodiment. FIG. 38 illustrates a result of photographing using the substrate type sensor 200 according to an example embodiment. FIG. 39 is a perspective view illustrating at least a portion of the substrate type sensor 200 according to an example embodiment. FIG. 40 illustrates a result of photographing using the substrate type sensor 200 according to an example embodiment. FIGS. 35 to 40 are drawings of the substrate type sensor 200 including light members 250 having a structure protruding from the second surface 210-2. Further, FIG. 38 and FIG. 40 specifically illustrate the results taken by the shooting apparatus 220 of the substrate type sensor 200.

In an example embodiment, the substrate type sensor 200 may include the light members 250 having a structure protruding from the second surface 210-2. The light members 250 may be placed in a location that does not overlap the groove 210H when viewed from the second direction D2. In other words, the light member 250 may not be placed in the groove 210H.

In an example embodiment, the length h₃₀₀ of the ring structure 300 with respect to the second direction D2 may be greater than the sum hₛ of the length h₁₅₁ of the chuck 151 and the length h200 of the substrate type sensor 200. In this case, the substrate type sensor 200 including the light members 250 may be more advantageous in obtaining high quality photographing results.

In an example embodiment, the light members 250 may include a first light member 250-1 and a second light member 250-2 extended and arranged along the first direction D1 of the second part 210H-2. In other words, the multiple light members 250 may be arranged on the second surface 210-2 of the substrate type sensor 200. Further, the second part 210H-2 may be positioned between the first light member 250-1 and the second light member 250-2. Specifically, when viewed from first direction D1, the second part 210H-2 may be positioned between the first light member 250-1 and the second light member 250-2. Further, when viewed from the third direction D3, the first light member 250-1 and the second light member 250-2 may overlap at least partially. Through this, since the light members 250 are shot by extending from the groove wall surface 210HW to the second direction D2 in the shooting results, when the length h₃₀₀ of the ring structure 300 based on the second direction D2 is greater than the sum hₛ of the length h₁₅₁ of the chuck 151 and the length h200 of the substrate type sensor 200, the standard for measuring the length h₃₀₀ of ring structure 300 based on the second direction D2 with the light member 250 may be established.

In an example embodiment, each of the light members 250 may include a wall surface of the light member 250 that is photographed by the shooting apparatus 220. Specifically, the first light member 250-1 may include a wall surface 250-1W, which is a portion that is photographed by the shooting apparatus 220, and the second light member 250-2 may include a wall surface 250-2W, which is a portion that is photographed by the shooting apparatus 220 (see FIGS. 37 and 38).

In an example embodiment, the substrate type sensor 200 may include the reference marks 210M disposed on the light members 250 (see FIG. 39). In an example embodiment, the reference marks 210M may be photographed by the shooting apparatus 220 (see FIG. 40). In other words, the reference marks 210M may appear in the shooting results. With regard to the reference marks 210M, the descriptions of the reference mark 210M placed in the groove 210H may be referred to as long as the descriptions are not contradictory. For example, features that differ from the above descriptions are described, and duplicative descriptions are not repeated.

In an example embodiment, the reference marks 210M may include the first reference mark 210M-1 disposed on the wall surface 250-1W of the first light member 250-1 and the second reference mark 210M-2 placed on the wall surface 250-2W of the second light member 250-2. Further, in an example embodiment, the reference marks 210M may include the first reference mark 210M-1 and the second reference mark 210M-2 spaced apart from each other by a predetermined separation distance WM with respect to the third direction D3.

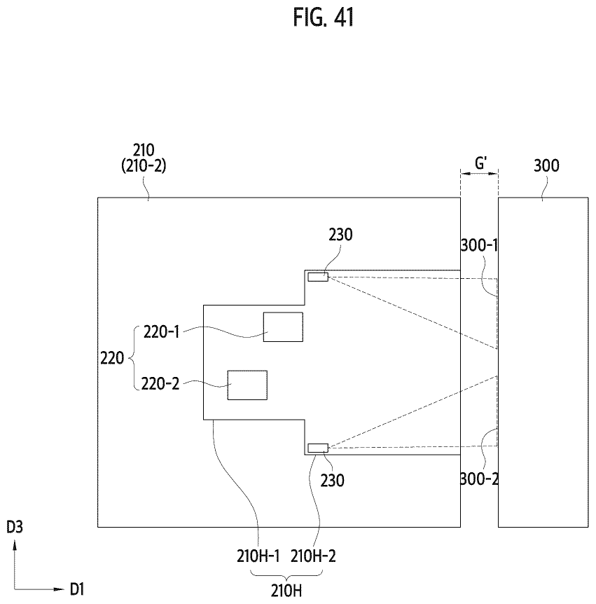

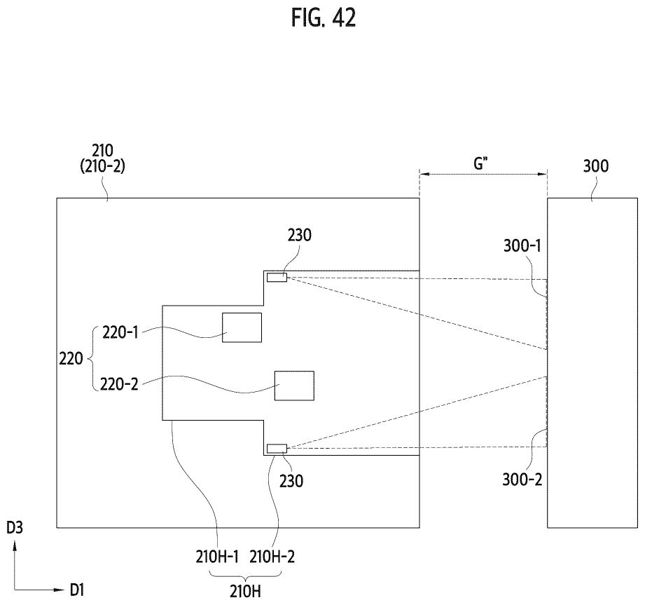

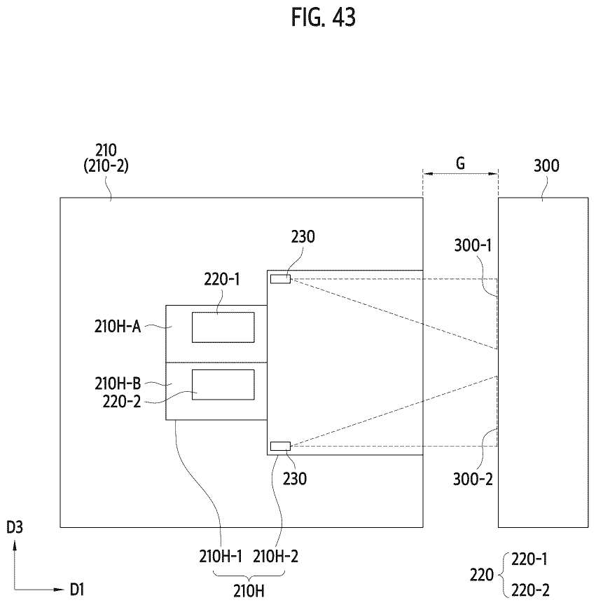

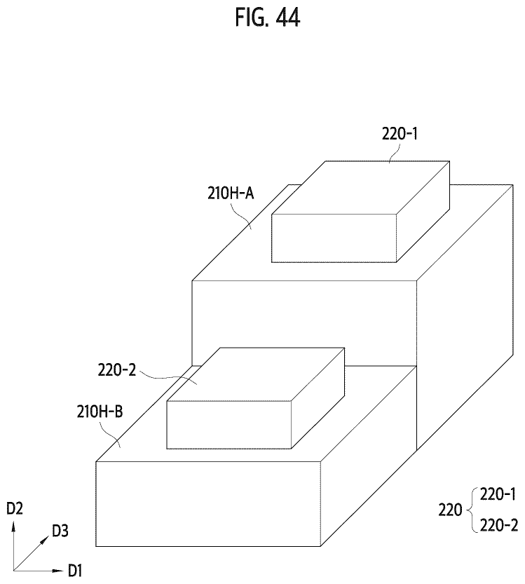

As an enlarged view of a portion A3 of FIG. 13, FIG. 41 is a plan view illustrating at least a portion of the substrate type sensor 200 and at least a portion of the ring structure 300 according to an example embodiment. As an enlarged view of a portion A4 of FIG. 18, FIG. 42 is a plan view illustrating at least a portion of the substrate type sensor 200 and at least a portion of the ring structure 300 according to an example embodiment. As an enlarged view of the portion A2 of FIG. 2, FIG. 43 is a plan view illustrating at least a portion of the substrate type sensor 200 and at least a portion of the ring structure 300 according to an example embodiment. FIG. 44 is a perspective view illustrating the shooting apparatus 220 according to an example embodiment.

In an example embodiment, the substrate type sensor 200 may include a plurality of shooting apparatuses 220 in a single groove 210H.

Referring to FIG. 41, the shooting apparatuses 220 may include a first shooting apparatus 220-1 that is placed to be spaced further from the ring structure 300 than the light apparatus 230 in the first direction D1 (in other words, further apart in the −first direction (−D1) in the drawing), and a second shooting apparatus 220-2 that is placed to be spaced further from the ring structure 300 than the first shooting apparatus 220-1 in the first direction (in other words, further apart in the −first direction (−D1) in the drawing). In an example embodiment, the first shooting apparatus 220-1 and the second shooting apparatus 220-1 may be disposed in the first part 210H-1 of the groove 210H. In an example embodiment, when the second separation distance G′ is shorter than the first separation distance G described above (see FIGS. 13 to 17, right side), arranging the multiple shooting apparatuses (the first shooting apparatus 220-1, and the second shooting apparatus 220-2) as described above may be more advantageous in obtaining high-quality shooting results. Specifically, it may be more advantages in obtaining high quality shooting results that when the second separation distance G′ is shorter than the first separation distance G mentioned above, the shooting apparatuses 220 are arranged further apart from the ring structure 300 than the light apparatus 230 in the first direction D1, thereby minimizing interference between reflected lights due to the shortened separation distance, the first shooting apparatus 220-1 maintains resolution, and the second shooting apparatus 220-2 provides a wider angle of view.

Referring to FIG. 42, the shooting apparatus 220 may include the first shooting apparatus 220-1 that is paced to be spaced further apart from the ring structure 300 than the light apparatus 230 in the first direction D1 (in other words, further apart in the −first direction (−D1) in the drawing), and the second shooting apparatus 220-2 that is placed to be closer to the ring structure 300 than the light apparatus 230 in the first direction (in other words, closer to +first direction (+D1) in the drawing). In an example embodiment, the first shooting apparatus 220-1 may be disposed in the first part 210H-1 of the groove 210H, and the second shooting apparatus 220-1 may be disposed in the second part 210H-2 of the groove 210H. In an example embodiment, it may be more advantageous in obtaining high quality shooting results that when the second separation distance G′ is longer than the first separation distance G described above (see FIGS. 18 to 22, left side), the first shooting apparatus 220-1 is positioned further away from the ring structure 300 in the first direction D1 than the light apparatus 230 to maintain the field of view, and the first shooting apparatus 220-1 is located closer to the ring structure 300 in the first direction D1 than the light apparatus 230, thereby reducing the loss of light that is irradiated from the light apparatus 230 and reflected by the ring structure 300 and improving resolution.

Referring to FIG. 43 and FIG. 44, the groove 210H may include a third part 210H-A and a fourth part 210H-B closer to the first surface 210-1 based on the second direction D2 compared to the third part 210H-A. For example, the fourth part 210H-B may be recessed further from the second surface 210-2 than the third part 210H-A. Further, the substrate type sensor 200 may include the plurality of shooting apparatuses 220, and at least one of the plurality of shooting apparatuses 220 (for example, the first shooting apparatus 220-1) may be arranged in the third part 210H-A, and at least another one of the plurality of shooting apparatuses 220 (for example, the second shooting apparatus 220-2) may be arranged in the fourth part 210H-B. Meanwhile, at least some of the plurality of shooting apparatuses 220 may be arranged further apart from the ring structure 300 in the first direction D1 (in other words, further apart in the −first direction (−D1) in the drawing) than the light apparatus 230. Further, at least some of the plurality of shooting apparatuses 220 may be positioned closer to the ring structure 300 than the light apparatus 230 in the first direction D1 (in other words, closer to +first direction (+D1) in the drawing). Further, at least two of the multiple shooting apparatuses 220 may be placed in each of the third part 210H-A and the fourth part 210H-B, and the shooting apparatuses 220 may be arranged side-by-side based on the first direction D1. The height difference (the length difference in the second direction D2) between the third part 210H-A and the fourth part 210H-B is not particularly limited and may vary depending on the design. In an example embodiment, the third part 210H-A and the fourth part 210H-B may be disposed at least in the first part 210H-1. In an example embodiment, the third part 210H-A and the fourth part 210H-B may be disposed in both the first part 210H-1 and the second part 210H-2.

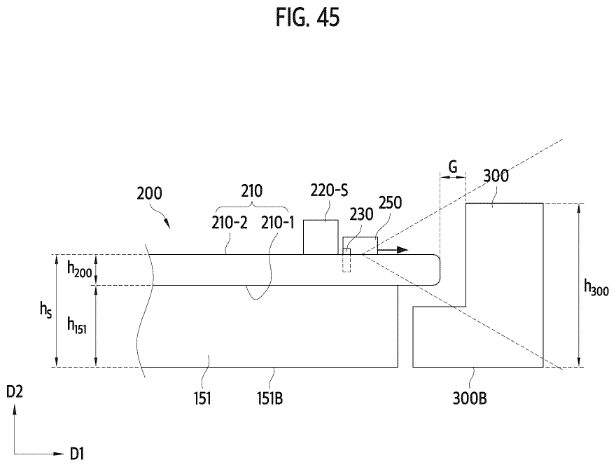

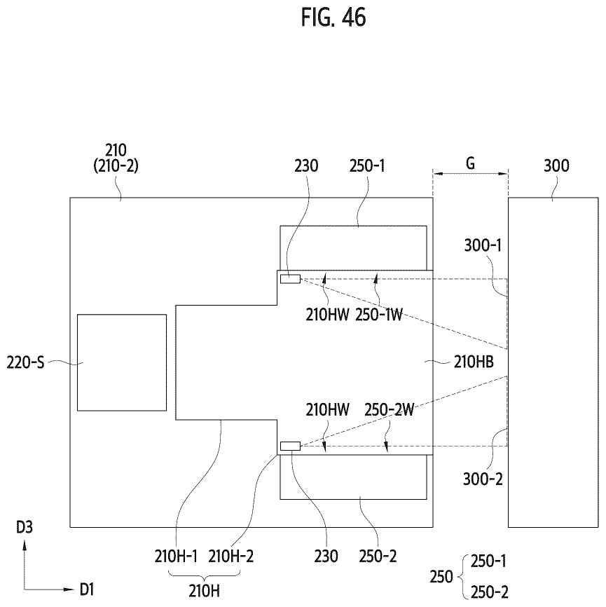

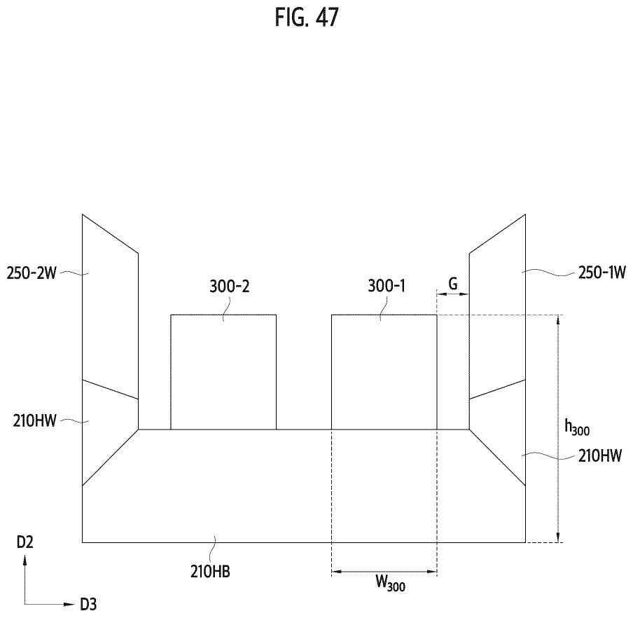

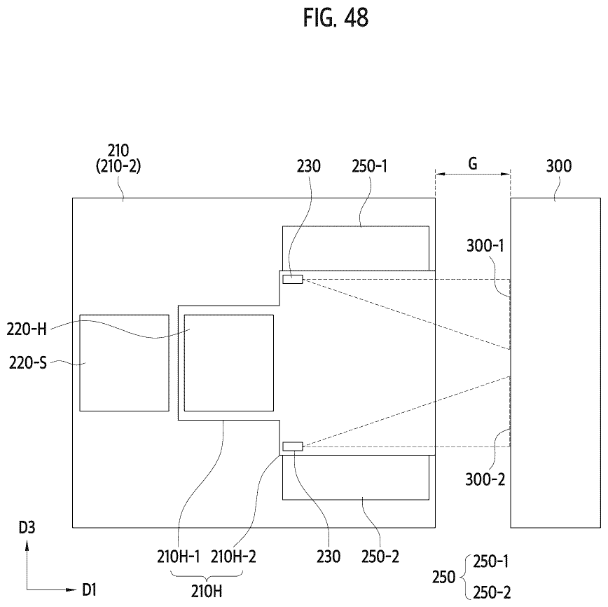

As an enlarged view of the portion A1 of FIG. 1, FIG. 45 is a cross-sectional view illustrating at least a portion of the substrate processing equipment 10 according to an example embodiment. As an enlarged view of the portion A2 of FIG. 2, FIG. 46 is a plan view illustrating at least a portion of the substrate type sensor 200 and at least a portion of the ring structure 300 according to an example embodiment. FIG. 47 illustrates a result of photographing using the substrate type sensor 200 according to an example embodiment. As an enlarged view of the portion A2 of FIG. 2, FIG. 48 is a plan view illustrating at least a portion of the substrate type sensor 200 and at least a portion of the ring structure 300 according to an example embodiment. For descriptions of FIGS. 45 to 48, the descriptions of FIGS. 1 to 44 may be referred to, unless the descriptions are contradictory. Below, example embodiments that differ from the above descriptions are described, and duplicative descriptions are not repeated. Further, FIG. 47 specifically illustrates the shooting result taken by the shooting apparatus 220 of the substrate type sensor 200.

In an example embodiment, the substrate type sensor 200 may be placed in the body part 210, and may include a surface part shooting apparatus 220-S arranged so as not to overlap the groove 210H when viewed from the second direction D2. In other words, the surface part shooting apparatus 220-S may not be placed in the groove 210H. Except for the placement positions, with regard to the surface part shooting apparatus 220-S, the descriptions of the aforementioned shooting apparatus 220 may be referred to, unless the descriptions are contradictory. For example, the surface part shooting apparatus 220-S may shoot at least a portion of one side of the groove 210H and at least a portion of one side of the ring structure 300.

In an example embodiment, when the substrate type sensor 200 includes a surface part shooting apparatus 200-S, the substrate type sensor 200 may include the light members 250 having a structure protruding from the second surface 210-2. The light members 250 may be placed in a location that does not overlap the groove 210H when viewed from the second direction D2. In other words, the light members 250 may not be placed in the groove 210H.

In an example embodiment, each of the light members 250 may include a wall surface of the light member 250, which is a portion that is photographed by the surface part shooting apparatus 220-S. As described above, the light members 250 may include the first light member 250-1 and the second light member 250-2 extended and arranged along the first direction D1 of the second part 210H-2. Specifically, the first light member 250-1 may include the wall surface 250-1W of the first light member 250-1, which is a portion that is photographed by the shooting apparatus 220, and the second light member 250-2 may include the wall surface 250-2W of the second light member 250-2, which is a portion that is photographed by the shooting apparatus 220 (see FIGS. 46 and 47). When the substrate type sensor 200 includes the surface part shooting apparatus 220-S, through the light member 250, the control apparatus 240 may quantitatively calculate the etched amount of the ring structure 300. The above descriptions may be referred to for the method for calculating the etched amount unless the descriptions are contradictory.

In an example embodiment, the substrate type sensor 200 may include a groove shooting apparatus 220-H that is positioned in the groove 210H and configured to photograph at least a portion of one side of the groove 210H and at least a portion of one side of the ring structure 300. The descriptions of the shooting apparatus 220 may be referred to for the groove shooting apparatus 220-H, unless the descriptions are contradictory.

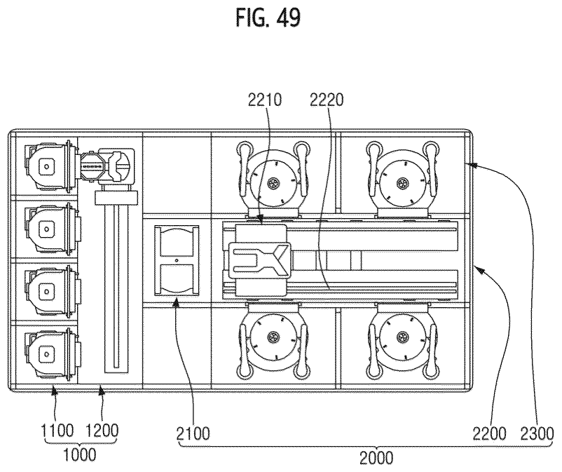

FIG. 49 is a plan view illustrating at least a portion of a substrate processing system according to an example embodiment. In an example embodiment, the substrate processing system may include an index module 1000 and a processing module 2000.

In an example embodiment, the index module 1000 receives a substrate from outside and returns the substrate to the processing module 2000. The processing module 2000 may perform the lithography process, the ashing process, the ion implantation process, the thin film deposition process, and/or the cleaning process. The index module 1000 may be an equipment front end module (EFEM). The index module 1000 may contain a load port 1100 and a transfer frame 1200.

In an example embodiment, the load port 1100 may accommodate a substrate. The substrate may be placed in a container within the load port 1100. A front opening unified pod (FOUP) may be used as the container. The container may be taken in from outside to the load port 1100 by overhead transfer (OHT). The container may be taken out from the load port 1100 by the OHT. The transfer frame 1200 may transfer the substrate between the container placed at the load port 1100 and the processing module 2000.

In an example embodiment, the processing module 2000 may be a module that actually performs the process. The processing module 2000 may include a buffer chamber 2100, a transfer chamber 2200, and processing equipment 2300. In an example embodiment, the processing equipment 2300 may be in a tower form including multiple process chambers, but the processing equipment 2300 is not limited thereto.

In an example embodiment, the buffer chamber 2100 provides a space for temporarily holding the substrate being returned between the index module 1000 and the processing module 2000. The buffer chamber 2100 may provide a buffer slot into which the substrate is placed. A transfer robot 2210 of the transfer chamber 2200 may take out the substrate placed in the buffer slot and return it to the processing equipment 2300. The buffer chamber 2100 may provide multiple buffer slots.

In an example embodiment, the transfer chamber 2200 transfers the substrate between the buffer chamber 2100 arranged around the transfer chamber 2200 and the processing equipment 2300. The transfer chamber 2200 may include the transfer robot 2210 and a transfer rail 2220. The transfer robot 2210 may move on the transfer rail 2220 and return the substrate.

In an example embodiment, the processing equipment 2300 may be the substrate processing equipment 10. For example, the lithography process, the ashing process, the ion implantation process, the thin film deposition process, and/or the cleaning process may be performed within the processing equipment 2300.

In an example embodiment, a piece of the processing equipment 2300 may be positioned on one side of the transfer chamber 2200. Another piece of the processing equipment 2300 may be placed on the other side of the transfer chamber 2200. In other words, a plurality of pieces of the processing equipment 2300 may be positioned facing each other on different sides of the transfer chamber 2200.

In an example embodiment, a plurality of pieces of processing equipment 2300 may be provided in the processing module 2000. The plurality of pieces of processing equipment 2300 may be arranged in a row on one side of the transfer chamber 2200. However, the present disclosure is not limited thereto.

In an example embodiment, the arrangement of the plurality of pieces of processing equipment 2300 is not limited to the above-described example embodiments. The arrangement of the plurality of pieces of processing equipment 2300 may be changed depending on the equipment footprint or process efficiency.

The example embodiments of the present disclosure are described with reference to the attached drawings. However, the present disclosure is not limited to the example embodiments, and the present disclosure can be manufactured in various other forms, and a person skilled in the art to which the present disclosure pertains will understand that the present disclosure can be implemented in other specific forms without changing its technical idea or essential features. Therefore, the example embodiments described above should be understood in all respects as illustrative and not limiting.

What is claimed is:

1. Substrate processing equipment comprising:
a substrate supporter comprising a chuck comprising a receiving surface that is flat and on which a substrate is placed;
a ring structure that is placed along an edge of the substrate supporter at a predetermined distance in a first direction parallel to the receiving surface; and
a substrate type sensor that is placed on the receiving surface,
wherein the substrate type sensor comprises:
a body part comprising a first surface facing the receiving surface based on a second direction perpendicular to the receiving surface and a second surface that is an opposite surface of the first surface, wherein a groove is formed on at least a portion of an edge of the second surface;
a shooting apparatus that is placed at the groove and configured to shoot at least one surface of the groove and at least a portion of one side of the ring structure; and
a control apparatus configured to control the shooting apparatus and calculate length of the ring structure in the second direction.

2. The substrate processing equipment of claim 1, wherein the control apparatus is configured to derive an etched amount of the ring structure by calculating a length difference of the ring structure in the second direction with respect to before and after etching the substrate.

3. The substrate processing equipment of claim 1,
wherein the substrate type sensor further comprises:
a first region that is formed between the substrate type sensor and the ring structure, and formed in one side based on the first direction; and
a second region that is formed between the substrate type sensor and the ring structure, and formed on another side based on the first direction, and
wherein the control apparatus is configured to further calculate a difference between a first separation distance that is a separation distance of the first region when the separation distance of the first region and a separation distance of the second region are identical and a second separation distance that is the separation distance of the first region when the separation distance of the first region and the separation distance of the second region are different.

4. The substrate processing equipment of claim 1,
wherein the groove comprises a first part that is closer to a center of the substrate type sensor and a second part other than the first part, based on the first direction,
wherein at least a portion of the shooting apparatus is placed at the first part, and
wherein the second part has a width that is greater than a width of the first part, based on a third direction perpendicular to the first direction and the second direction.

5. The substrate processing equipment of claim 1,
wherein the substrate type sensor comprises a reference mark that is placed at the groove,
wherein the reference mark comprises a first reference mark and a second reference mark that are spaced apart from each other at a predetermined distance, with respect to a third direction that is perpendicular to the first direction and the second direction, and
wherein the reference mark is shot by the shooting apparatus.

6. The substrate processing equipment of claim 1, wherein the substrate type sensor further comprises a light apparatus that is placed at the groove, and configured to irradiate light in order for light reflected from the ring structure to be incident to the shooting apparatus.

7. The substrate processing equipment of claim 6,
wherein a plurality of light apparatuses are present, and
wherein the shooting apparatus is placed between the plurality of light apparatuses when viewed in the first direction.

8. The substrate processing equipment of claim 6, wherein the light apparatus is configured to irradiate light between an angle toward the first direction and an angle toward the second direction.

9. The substrate processing equipment of claim 8,
wherein the ring structure comprises at least a portion that is an inclined surface facing the substrate type sensor in the first direction, and
wherein the light apparatuses are configured to irradiate light between an angle toward the first direction and an angle toward the second direction, and irradiate light beyond the angle toward the first direction.

10. The substrate processing equipment of claim 8,
wherein the chuck further comprises a supporting surface that is flat and opposite to the receiving surface,
wherein the supporting surface is placed to be coplanar with a lower portion surface that is placed at a lower part of the ring structure based on the second direction,
wherein the ring structure comprises a length that is greater than a sum of a length of the chuck and a length of the substrate type sensor based on the second direction, and
wherein the light apparatuses are configured to irradiate light between an angle toward the first direction and an angle toward the second direction, and irradiate light beyond the angle toward the first direction.

11. The substrate processing equipment of claim 1,
wherein the substrate type sensor further comprises a light member having a structure protruding from the second surface, and
wherein the light member does not overlap the groove when viewed in the second direction.

12. The substrate processing equipment of claim 11,
wherein the groove comprises a first part that is closer to the center of the substrate type sensor and a second part other than the first part, based on the first direction, and
wherein the light member comprises a first light member and a second light member that are placed to extend along the first direction of the second part, and the second part is placed between the first light member and the second light member.

13. The substrate processing equipment of claim 12,
wherein the substrate type sensor comprises a reference mark that is placed at the light member, and
wherein the reference mark comprises:
a first reference mark that is placed on a wall surface of the first light member; and
a second reference mark that is placed on a wall surface of the second light member, and is spaced apart from the first reference mark at a predetermined separation distance in a third direction perpendicular to the first direction and the second direction, and
wherein the reference mark is shot by the shooting apparatus.

14. The substrate processing equipment of claim 6, wherein the shooting apparatus comprising:
a first shooting apparatus that is placed to be spaced further from the ring structure than the light apparatus in the first direction; and
a second shooting apparatus that is place to be spaced further from the ring structure than the first shooting apparatus in the first direction.

15. The substrate processing equipment of claim 6, wherein the shooting apparatus comprises:
a first shooting apparatus that is placed to be spaced further from the ring structure than the light apparatus in the first direction; and
a second shooting apparatus that is placed closer to the ring structure than the light apparatus in the first direction.

16. The substrate processing equipment of claim 1, wherein the groove comprises a third part and a fourth part that is closer to the first surface than the third part in the second direction.

17. The substrate processing equipment of claim 16, wherein when a plurality of shooting apparatuses are present, at least two or more of the plurality of shooting apparatuses are placed at the third part, and at least two or more other shooting apparatuses among the plurality of shooting apparatuses are placed at the fourth part.

18. Substrate processing equipment comprises:
a substrate supporter comprising a chuck comprising a receiving surface that is flat and on which a substrate is placed;
a ring structure that is placed along an edge of the substrate supporter at a predetermined distance in a first direction parallel to the receiving surface; and
a substrate type sensor that is placed on the receiving surface,
wherein the substrate type sensor comprises:
a body part comprising a first surface facing the receiving surface based on a second direction perpendicular to the receiving surface and a second surface that is an opposite surface of the first surface, wherein a groove is formed on at least a portion of an edge of the second surface;
a surface part shooting apparatus that is placed at the body part and does not overlap the groove when viewed from the second direction;
a control apparatus configured to control the surface part shooting apparatus and calculate a length of the ring structure in the second direction; and
a light member that does not overlap the groove when viewed in the second direction and has a structure protruding from the second surface.

19. The substrate processing equipment of claim 18, wherein the substrate type sensor further comprises a groove shooting apparatus that is placed at the groove and configured to shoot at least one surface of the groove and at least a portion of one side of the ring structure.

20. Substrate processing equipment comprising:
a chamber that is at least a portion of a processing space where a substrate is processed;
a source supplying apparatus configured to generate at least one of plasma and radical;
a shower head configured to distribute the at least one of the plasma and the radical to the processing space;
a substrate supporter comprising a chuck comprising a receiving surface that is flat and on which the substrate is placed;
a ring structure that is placed along an edge of the substrate supporter at a predetermined distance in a first direction parallel to the receiving surface; and
a substrate type sensor that is placed on the receiving surface,
wherein the substrate type sensor comprises:
a body part comprising a first surface facing the receiving surface based on a second direction perpendicular to the surface of the receiving surface and a second surface that is an opposite surface of the first surface, wherein a groove is formed on at least a portion of an edge of the second surface;
a shooting apparatus that is placed at the groove and configured to shoot at least one surface of the groove and at least a portion of one side of the ring structure;
a control apparatus configured to control the shooting apparatus and calculate a length of the ring structure in the second direction;
a first region that is formed between the substrate type sensor and the ring structure, and formed in one side based on the first direction; and
a second region that is formed between the substrate type sensor and the ring structure, and formed on another side based on the first direction, and
wherein the control apparatus is configured to:
derive an etched amount of the ring structure by calculating a length difference of the ring structure in the second direction with respect to before and after etching the substrate; or
calculate a difference between a first separation distance that is a separation distance of the first region when the separation distance of the first region and a separation distance of the second region are identical and a second separation distance that is the separation distance of the first region when the separation distance of the first region and the separation distance of the second region are different.
